(19) United States
(12) Patent Application Publication
(10) Pub. No.: US 2025/0351480 A1
(43) Pub. Date: Nov. 13, 2025

(54) TRANSISTOR ISOLATION REGIONS AND METHODS OF FORMING THE SAME

(71) Applicant: Taiwan Semiconductor Manufacturing Co., Ltd., Hsinchu (TW)

(72) Inventors: Chung-Ting Ko, Kaohsiung City (TW); Tai-Jung Kuo, Hsinchu (TW); Sung-En Lin, Hsinchu (TW); Zhen-Cheng Wu, Hsinchu (TW); Chi On Chui, Hsinchu (TW)

(21) Appl. No.: 19/273,896

(22) Filed: Jul. 18, 2025

Related U.S. Application Data
(62) Division of application No. 17/742,943, filed on May 12, 2022.
(60) Provisional application No. 63/278,520, filed on Nov. 12, 2021.

(51) Int. Cl. H10D 62/10; H10D 30/01; H10D 30/67

(52) U.S. Cl. CPC H10D 62/118; H10D 30/031; H10D 30/6713; H10D 30/6757

(57) ABSTRACT

In an embodiment, a device includes: first source/drain regions; a first insulating fin between the first source/drain regions, the first insulating fin including a first lower insulating layer and a first upper insulating layer; second source/drain regions; and a second insulating fin between the second source/drain regions, the second insulating fin including a second lower insulating layer and a second upper insulating layer, the first lower insulating layer and the second lower insulating layer including the same dielectric material, the first upper insulating layer and the second upper insulating layer including different dielectric materials.

### PRIORITY CLAIM AND CROSS-REFERENCE

This application is a divisional of U.S. patent application Ser. No. 17/742,943, filed May 12, 2022, which application claims the benefit of U.S. Provisional Application No. 63/278,520, filed on Nov. 12, 2021, which applications are hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2-25F are views of intermediate stages in the manufacturing of nano-FETs, in accordance with some embodiments.

FIGS. 26A-26F are views of nano-FETs, in accordance with some other embodiments.

FIG. 27 illustrates a reaction when converting a low-density silicon carbide to a high-density silicon carbide.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, insulating fins are formed between source/drain regions. The insulating fins block epitaxial growth, thereby allowing the source/drain regions to remain separated after the epitaxial growth. Upper portions of the insulating fins between the source/drain regions are replaced with a material that provides better electrical isolation between adjacent source/drain regions. This can reduce leakage, thereby improving the performance of the resulting nano-FETs. Advantageously, the upper portions of the insulating fins that will be replaced are formed of different materials in different regions. Specifically, the upper portions of the insulating fins in dense regions are formed of a first dielectric material, and the upper portions of the insulating fins in sparse regions are formed of a second dielectric material that is different from the first dielectric material. The upper portions of the insulating fins in the different regions thus have etching selectivity from one another, allowing separate etching processes to be used when replacing the upper portions of the insulating fins in the different regions, thereby avoiding pattern loading effects.

Embodiments are described in a particular context, a die including nano-FETs. Various embodiments may be applied, however, to dies including other types of transistors (e.g., fin field-effect transistors (finFETs), planar transistors, or the like) in lieu of or in combination with the nano-FETs.

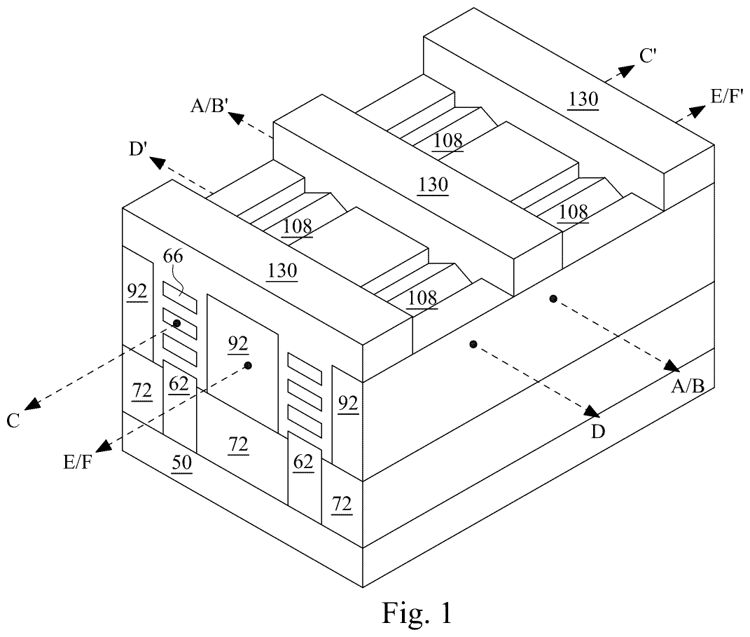

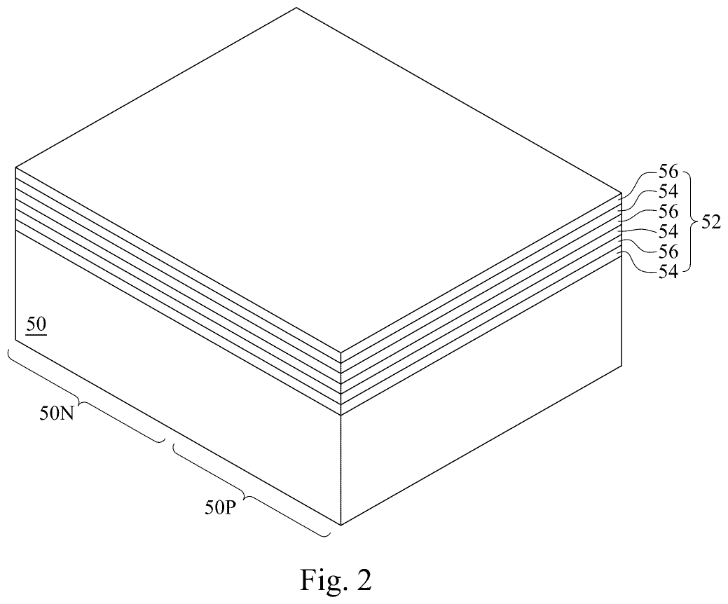

FIG. 1 illustrates an example of nano-FETs (e.g., nanowire FETs, nanosheet FETs, or the like), in accordance with some embodiments. FIG. 1 is a three-dimensional view, where some features of the nano-FETs are omitted for illustration clarity. The nano-FETs may be nanosheet field-effect transistors (NSFETs), nanowire field-effect transistors (NWFETs), gate-all-around field-effect transistors (GAAFETs), or the like.

The nano-FETs include nanostructures 66 (e.g., nanosheets, nanowires, or the like) over semiconductor fins 62 on a substrate 50 (e.g., a semiconductor substrate), with the nanostructures 66 acting as channel regions for the nano-FETs. The nanostructures 66 may include p-type nanostructures, n-type nanostructures, or a combination thereof. Isolation regions 72, such as shallow trench isolation (STI) regions, are disposed between adjacent semiconductor fins 62, which may protrude above and from between adjacent isolation regions 72. Although the isolation regions 72 are described/illustrated as being separate from the substrate 50, as used herein, the term “substrate” may refer to the semiconductor substrate alone or a combination of the semiconductor substrate and the isolation regions. Additionally, although the bottom portions of the semiconductor fins 62 are illustrated as being separate from the substrate 50, the bottom portions of the semiconductor fins 62 may be single, continuous materials with the substrate 50. In this context, the semiconductor fins 62 refer to the portion extending above and from between the adjacent isolation regions 72.

Gate structures 140 are over top surfaces of the semiconductor fins 62 and along top surfaces, sidewalls, and bottom surfaces of the nanostructures 66. Epitaxial source/drain regions 118 are disposed on the semiconductor fins 62 at opposing sides of the gate structures 140. The epitaxial source/drain regions 118 may be shared between various semiconductor fins 62. For example, adjacent epitaxial source/drain regions 118 may be electrically connected, such as through coupling the epitaxial source/drain regions 118 with a same source/drain contact.

Insulating fins 92, also referred to as hybrid fins or dielectric fins, are disposed over the isolation regions 72, and between adjacent epitaxial source/drain regions 118. The insulating fins 92 block epitaxial growth to prevent coalescing of some of the epitaxial source/drain regions 118 during epitaxial growth. For example, the insulating fins 92 may be formed at cell boundaries to separate the epitaxial source/drain regions 118 of adjacent cells.

FIG. 1 further illustrates reference cross-sections that are used in later figures. Cross-section A/B-A/B′ is along a longitudinal axis of a gate structure 140 and in a direction, for example, perpendicular to a direction of current flow between the epitaxial source/drain regions 118 of a nano-FET. Cross-section C-C′ is along a longitudinal axis of a semiconductor fin 62 and in a direction of, for example, a current flow between the epitaxial source/drain regions 118 of the nano-FET. Cross-section D-D′ is parallel to cross-section A/B-A/B′ and extends through epitaxial source/drain regions 118 of the nano-FETs. Cross-section E/F-E/F′ is parallel to cross-section C-C′ and is along a longitudinal axis of an insulating fin 92. Subsequent figures refer to these reference cross-sections for clarity.

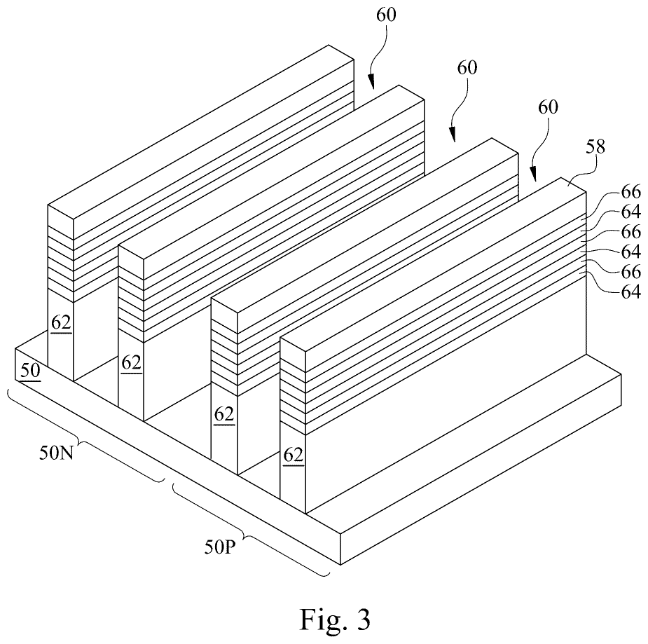

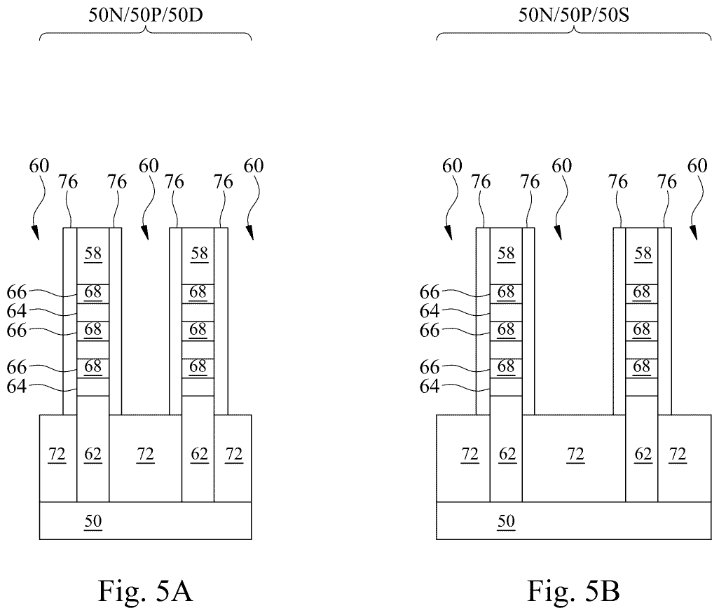

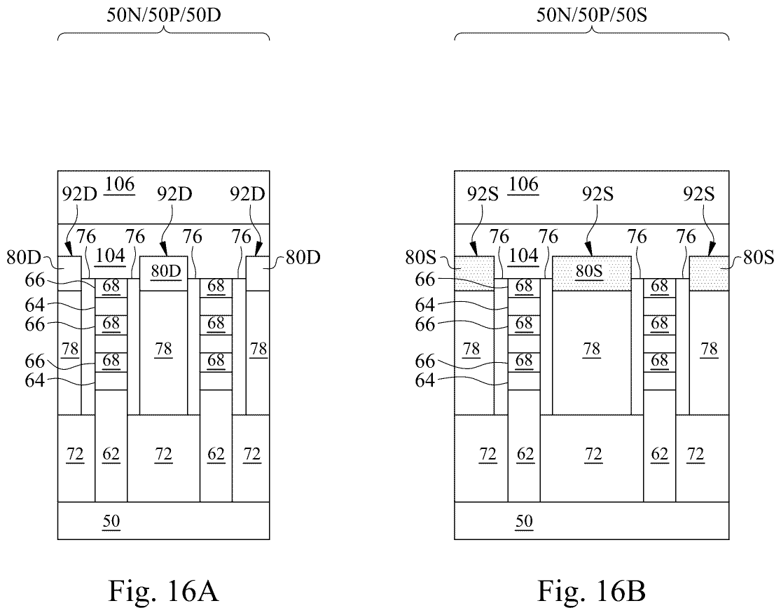

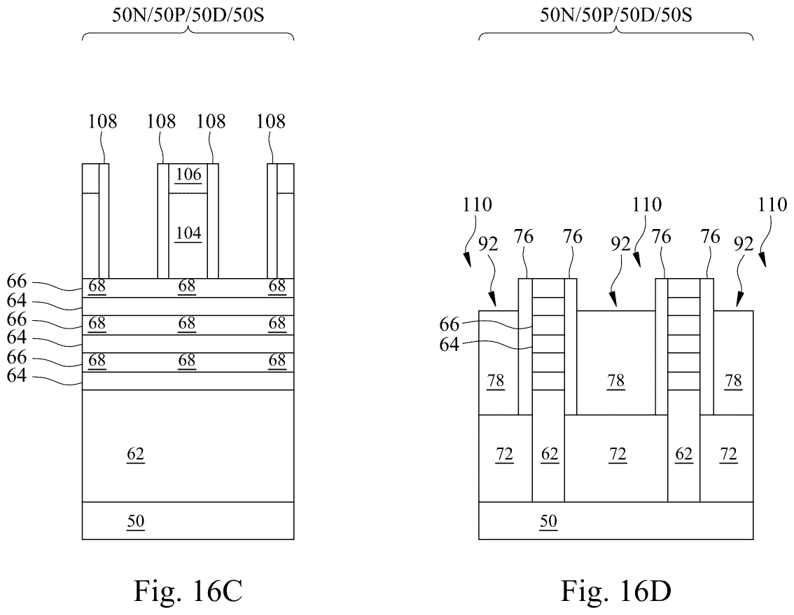

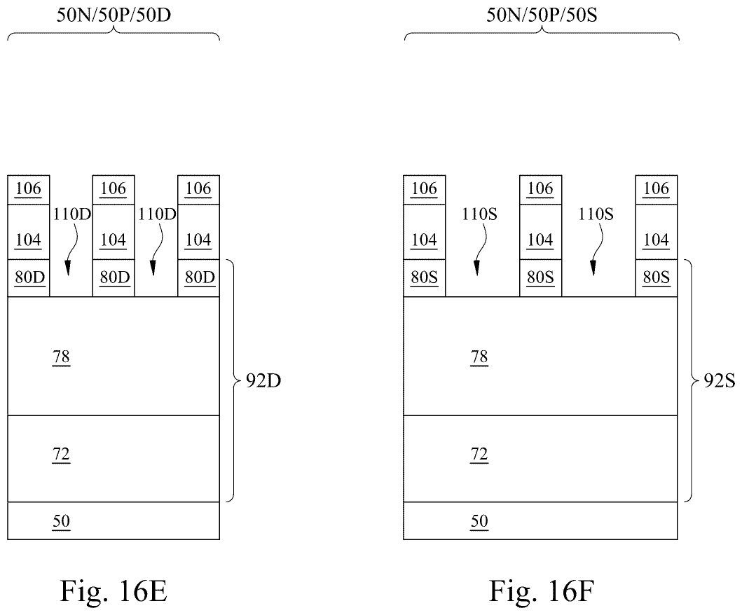

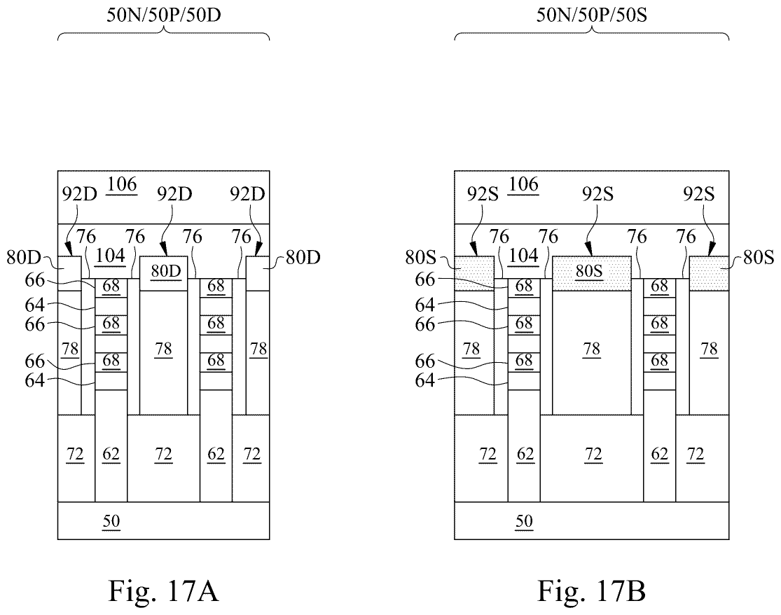

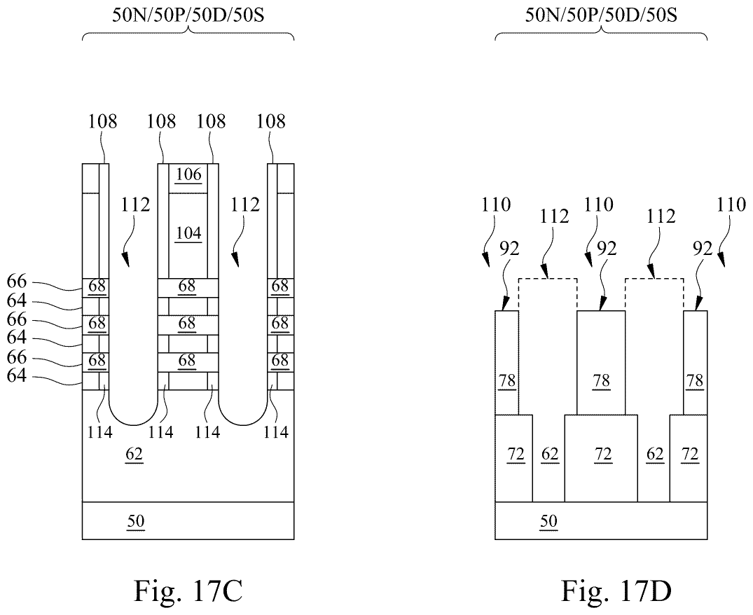

FIGS. 2-25F are views of intermediate stages in the manufacturing of nano-FETs, in accordance with some embodiments. FIGS. 2, 3, and 4 are three-dimensional views. FIGS. 5A, 5B, 6A, 6B, 7A, 7B, 8A, 8B, 9A, 9B, 10A, 10B, 11A, 11B, 12A, 12B, 13A, 13B, 14A, 14B, 15A, 15B, 16A, and 16B are cross-sectional views illustrated along a similar cross-section as either of reference cross-sections A/B-A/B′ or D-D′in FIG. 1. FIGS. 17A, 17B, 18A, 18B, 19A, 19B, 20A, 20B, 21A, 21B, 22A, 22B, 23A, 23B, 24A, 24B, 25A, and 25B are cross-sectional views illustrated along a similar cross-section as reference cross-section A/B-A/B′in FIG. 1. FIGS. 17C, 18C, 19C, 20C, 21C, 22C, 23C, 24C, and 25C are cross-sectional views illustrated along a similar cross-section as reference cross-section C-C′ in FIG. 1. FIGS. 16D, 17D, 18D, 19D, 20D, 21D, 22D, 23D, 24D, and 25D are cross-sectional views illustrated along a similar cross-section as reference cross-section D-D′in FIG. 1. FIGS. 16E, 16F, 19E, 19F, 25E, and 25F are cross-sectional views illustrated along a similar cross-section as reference cross-section E/F-E/F′ in FIG. 1.

In FIG. 2, a substrate 50 is provided for forming nano-FETs. The substrate 50 may be a semiconductor substrate, such as a bulk semiconductor, a semiconductor-on-insulator (SOI) substrate, or the like, which may be doped (e.g., with a p-type or an n-type impurity) or undoped. The substrate 50 may be a wafer, such as a silicon wafer. Generally, a SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; combinations thereof; or the like.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

The substrate 50 may be lightly doped with a p-type or an n-type impurity. An anti-punch-through (APT) implantation may be performed on an upper portion of the substrate 50 to form an APT region. During the APT implantation, impurities may be implanted in the substrate 50. The impurities may have a conductivity type opposite from a conductivity type of source/drain regions that will be subsequently formed in each of the n-type region 50N and the p-type region 50P. The APT region may extend under the source/drain regions in the nano-FETs. The APT region may be used to reduce the leakage from the source/drain regions to the substrate 50. In some embodiments, the doping concentration in the APT region is in the range of 10¹⁸ cm⁻³ to 10¹⁹ cm⁻³.

A multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50. In the illustrated embodiment, the multi-layer stack 52 includes three layers of each of the first semiconductor layers 54 and the second semiconductor layers 56. It should be appreciated that the multi-layer stack 52 may include any number of the first semiconductor layers 54 and the second semiconductor layers 56. For example, the multi-layer stack 52 may include from one to ten layers of each of the first semiconductor layers 54 and the second semiconductor layers 56.

In the illustrated embodiment, and as will be subsequently described in greater detail, the first semiconductor layers 54 will be removed and the second semiconductor layers 56 will patterned to form channel regions for the nano-FETs in both the n-type region 50N and the p-type region 50P. The first semiconductor layers 54 are sacrificial layers (or dummy layers), which will be removed in subsequent processing to expose the top surfaces and the bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nano-FETs in one region (e.g., the p-type region 50P), and the second semiconductor layers 56 will be patterned to form channel regions for nano-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of 0 to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without removing the second semiconductor layers 56 in the n-type region 50N, and the second semiconductor layers 56 may be removed without removing the first semiconductor layers 54 in the p-type region 50P.

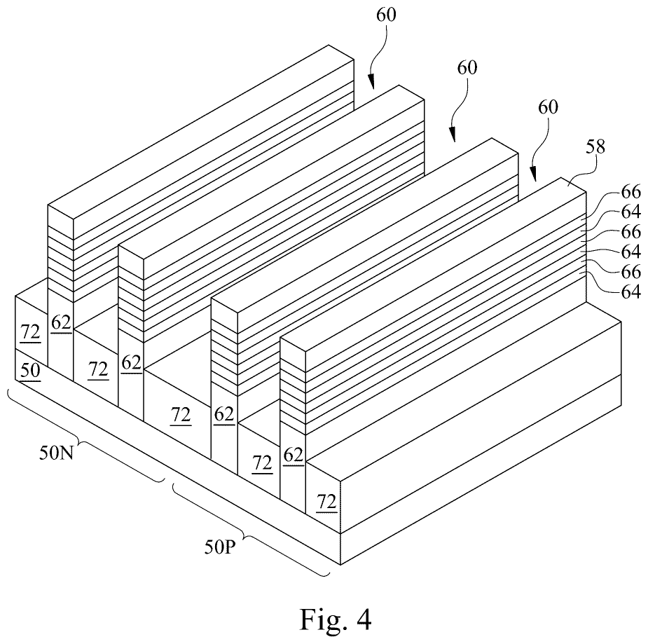

In FIG. 3, trenches 60 are patterned in the substrate 50 and the multi-layer stack 52 to form semiconductor fins 62, nanostructures 64, and nanostructures 66. The semiconductor fins 62 are semiconductor strips patterned in the substrate 50. The nanostructures 64 and the nanostructures 66 include the remaining portions of the first semiconductor layers 54 and the second semiconductor layers 56, respectively. The trenches 60 may be patterned by any acceptable etching process, such as a reactive ion etch (RIE), neutral beam etch (NBE), the like, or a combination thereof. The etching may be anisotropic.

The semiconductor fins 62 and the nanostructures 64, 66 may be patterned by any suitable method. For example, the semiconductor fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as a mask 58 to pattern the semiconductor fins 62 and the nanostructures 64, 66.

In some embodiments, the semiconductor fins 62 and the nanostructures 64, 66 each have widths in a range of 8 nm to 40 nm. In the illustrated embodiment, the semiconductor fins 62 and the nanostructures 64, 66 have substantially equal widths in the n-type region 50N and the p-type region 50P. In another embodiment, the semiconductor fins 62 and the nanostructures 64, 66 in one region (e.g., the n-type region 50N) are wider or narrower than the semiconductor fins 62 and the nanostructures 64, 66 in another region (e.g., the p-type region 50P). Further, while each of the semiconductor fins 62 and the nanostructures 64, 66 are illustrated as having a consistent width throughout, in other embodiments, the semiconductor fins 62 and/or the nanostructures 64, 66 may have tapered sidewalls such that a width of each of the semiconductor fins 62 and/or the nanostructures 64, 66 continuously increases in a direction towards the substrate 50. In such embodiments, each of the nanostructures 64, 66 may have a different width and be trapezoidal in shape.

In FIG. 4, STI regions 72 are formed over the substrate 50 and in the trenches 60 between adjacent semiconductor fins 62. The STI regions 72 are disposed around at least a portion of the semiconductor fins 62 such that at least a portion of the nanostructures 64, 66 protrude from between adjacent STI regions 72. In the illustrated embodiment, the top surfaces of the STI regions 72 are below the top surfaces of the semiconductor fins 62. In some embodiments, the top surfaces of the STI regions 72 are above or coplanar (within process variations) with the top surfaces of the semiconductor fins 62.

The STI regions 72 may be formed by any suitable method. For example, an insulation material can be formed over the substrate 50 and the nanostructures 64, 66, and in the trenches 60 between adjacent semiconductor fins 62. The insulation material may be an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. Other insulation materials formed by any acceptable process may be used. In some embodiments, the insulation material is silicon oxide formed by FCVD. An anneal process may be performed once the insulation material is formed. In an embodiment, the insulation material is formed such that excess insulation material covers the nanostructures 64, 66. Although the STI regions 72 are each illustrated as a single layer, some embodiments may utilize multiple layers. For example, in some embodiments a liner (not separately illustrated) may first be formed along surfaces of the substrate 50, the semiconductor fins 62, and the nanostructures 64, 66. Thereafter, an insulation material, such as those previously described may be formed over the liner.

A removal process is then applied to the insulation material to remove excess insulation material outside of the trenches 60, which excess material is over the nanostructures 64, 66. In some embodiments, a planarization process such as a chemical mechanical polish (CMP), an etch-back process, combinations thereof, or the like may be utilized. In some embodiments, the planarization process may expose the mask 58 or remove the mask 58. After the planarization process, the top surfaces of the insulation material and the mask 58 or the nanostructures 64, 66 are coplanar (within process variations). Accordingly, the top surfaces of the mask 58 (if present) or the nanostructures 64, 66 are exposed through the insulation material. In the illustrated embodiment, the mask 58 remains on the nanostructures 64, 66. The insulation material is then recessed to form the STI regions 72. The insulation material is recessed such that at least a portion of the nanostructures 64, 66 protrude from between adjacent portions of the insulation material. Further, the top surfaces of the STI regions 72 may have a flat surface as illustrated, a convex surface, a concave surface (such as dishing), or a combination thereof by applying an appropriate etch. The insulation material may be recessed using any acceptable etching process, such as one that is selective to the material of the insulation material (e.g., selectively etches the insulation material of the STI regions 72 at a faster rate than the materials of the semiconductor fins 62 and the nanostructures 64, 66). For example, an oxide removal may be performed using dilute hydrofluoric (dHF) acid as an etchant.

The process previously described is just one example of how the semiconductor fins 62 and the nanostructures 64, 66 may be formed. In some embodiments, the semiconductor fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the semiconductor fins 62 and/or the nanostructures 64, 66. The epitaxial structures may include the alternating semiconductor materials previously described, such as the first semiconductor material and the second semiconductor material. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the nanostructures 64, 66, the semiconductor fins 62, and/or the substrate 50. The wells may have a conductivity type opposite from a conductivity type of source/drain regions that will be subsequently formed in each of the n-type region 50N and the p-type region 50P. In some embodiments, a p-type well is formed in the n-type region 50N, and an n-type well is formed in the p-type region 50P. In some embodiments, a p-type well or an n-type well is formed in both the n-type region 50N and the p-type region 50P.

In embodiments with different well types, different implant steps for the n-type region 50N and the p-type region 50P may be achieved using mask (not separately illustrated) such as a photoresist. For example, a photoresist may be formed over the semiconductor fins 62, the nanostructures 64, 66, and the STI regions 72 in the n-type region 50N. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in the range of 10¹³ cm⁻³ to 10¹⁴ cm⁻³. After the implant, the photoresist may be removed, such as by any acceptable ashing process.

Following or prior to the implanting of the p-type region 50P, a mask (not separately illustrated) such as a photoresist is formed over the semiconductor fins 62, the nanostructures 64, 66, and the STI regions 72 in the p-type region 50P. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in the range of 10¹³ cm⁻³ to 10¹⁴ cm⁻³. After the implant, the photoresist may be removed, such as by any acceptable ashing process.

After the implants of the n-type region 50N and the p-type region 50P, an anneal may be performed to repair implant damage and to activate the p-type and/or n-type impurities that were implanted. In some embodiments where epitaxial structures are epitaxially grown for the semiconductor fins 62 and/or the nanostructures 64, 66, the grown materials may be in situ doped during growth, which may obviate the implantations, although in situ and implantation doping may be used together.

FIGS. 5A-25B illustrate various additional steps in the manufacturing of embodiment devices. FIGS. 5A-25B illustrate features in either of the n-type region 50N and the p-type region 50P. For example, the structures illustrated may be applicable to both the n-type region 50N and the p-type region 50P. Differences (if any) in the structures of the n-type region 50N and the p-type region 50P are described in the text accompanying each figure. Further, FIGS. 5A-25B illustrate features in a dense region 50D and a sparse region 50S. The gates structures in the dense region 50D have channel regions with short lengths, which may be desirable for some types of devices, such as devices that operate at high speeds. The gates structures in the sparse region 50S have channel regions with long lengths, which may be desirable for some types of devices, such as devices that operate at high power. More generally, the channel regions of the devices in the sparse region 50S are longer than the channel regions of the devices in the dense region 50D. Each of the regions 50D, 50S can include devices from both of the regions 50N, 50P. In other words, the dense region 50D and the sparse region 50S can each include n-type devices and p-type devices.

As will be subsequently described in greater detail, insulating fins 92 will be formed between the semiconductor fins 62. FIGS. 5A, 6A, 7A, 8A, 9A, 10A, 11A, 12A, 13A, 14A, 15A, 16A, 17A, 18A, 19A, 20A, 21A, 22A, 23A, 24A, and 25A each illustrate two semiconductor fins 62 and portions of the insulating fins 92 and the STI regions 72 that are disposed between the two semiconductor fins 62 in the dense region 50D. FIGS. 5B, 6B, 7B, 8B, 9B, 10B, 11B, 12B, 13B, 14B, 15B, 16B, 17B, 18B, 19B, 20B, 21B, 22B, 23B, 24B, and 25B each illustrate two semiconductor fins 62 and portions of the insulating fins 92 and the STI regions 72 that are disposed between the two semiconductor fins 62 in the sparse region 50S. FIGS. 16C, 17C, 18C, 19C, 20C, 21C, 22C, 23C, 24C, and 25C illustrate a semiconductor fin 62 and structures formed on it in either of the regions 50D, 50S. FIGS. 16D, 17D, 18D, 19D, 20D, 21D, 22D, 23D, 24D, and 25D each illustrate two semiconductor fins 62 and portions of the insulating fins 92 and the STI regions 72 that are disposed between the two semiconductor fins 62 in either of the regions 50D, 50S. FIGS. 16E, 19E, and 25E illustrate an insulating fin 92 and structures formed on it in the dense region 50D. FIGS. 16F, 19F, and 25F illustrate an insulating fin 92 and structures formed on it in the sparse region 50S.

In FIGS. 5A-5B, sacrificial spacers 76 are formed on the sidewalls of the mask 58, the semiconductor fins 62 and the nanostructures 64, 66, and further on the top surface of the STI regions 72. The sacrificial spacers 76 may be formed by conformally forming a sacrificial material in the trenches 60 and patterning the sacrificial material. The sacrificial material may be a semiconductor material selected from the candidate semiconductor materials of the substrate 50, which may be grown by a process such as vapor phase epitaxy (VPE) or molecular beam epitaxy (MBE), deposited by a process such as chemical vapor deposition (CVD) or atomic layer deposition (ALD), or the like. For example, the sacrificial material may be silicon or silicon germanium. The sacrificial material may be patterned using an etching process, such as a dry etch, a wet etch, or a combination thereof. The etching process may be anisotropic. As a result of the etching process, the portions of the sacrificial material over the mask 58 and the nanostructures 64, 66 are removed, and the STI regions 72 between the nanostructures 64, 66 are partially exposed. The sacrificial spacers 76 include the remaining portions of the sacrificial material in the trenches 60.

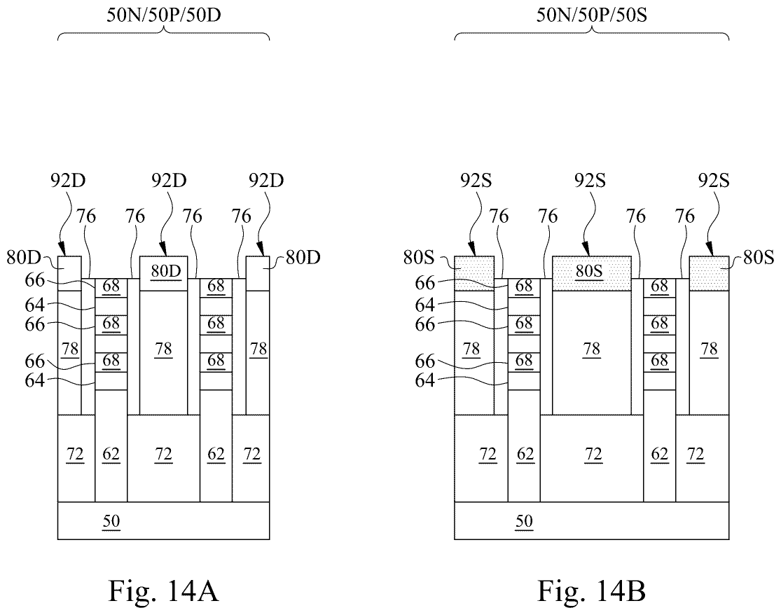

In subsequent process steps, a dummy gate layer 94 is deposited over portions of the sacrificial spacers 76 (see below, FIGS. 14A-14B), and the dummy gate layer 94 is patterned to form dummy gates 104 (see below, FIGS. 16A-16F). The dummy gates 104, the underlying portions of the sacrificial spacers 76, and the nanostructures 64 are then collectively replaced with functional gate structures. Specifically, the sacrificial spacers 76 are used as temporary spacers during processing to delineate boundaries of insulating fins, and the sacrificial spacers 76 and the nanostructures 64 will be subsequently removed and replaced with gate structures that are wrapped around the nanostructures 66. The sacrificial spacers 76 are formed of a material that has a high etching selectivity from the etching of the material of the nanostructures 66. For example, the sacrificial spacers 76 may be formed of the same semiconductor material as the nanostructures 64 so that the sacrificial spacers 76 and the nanostructures 64 may be removed in a single process step. Alternatively, the sacrificial spacers 76 may be formed of a different material from the nanostructures 66.

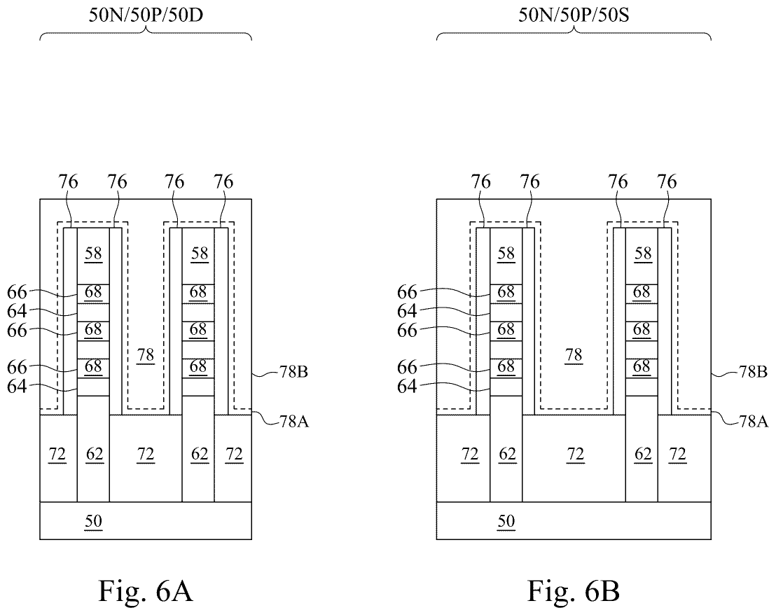

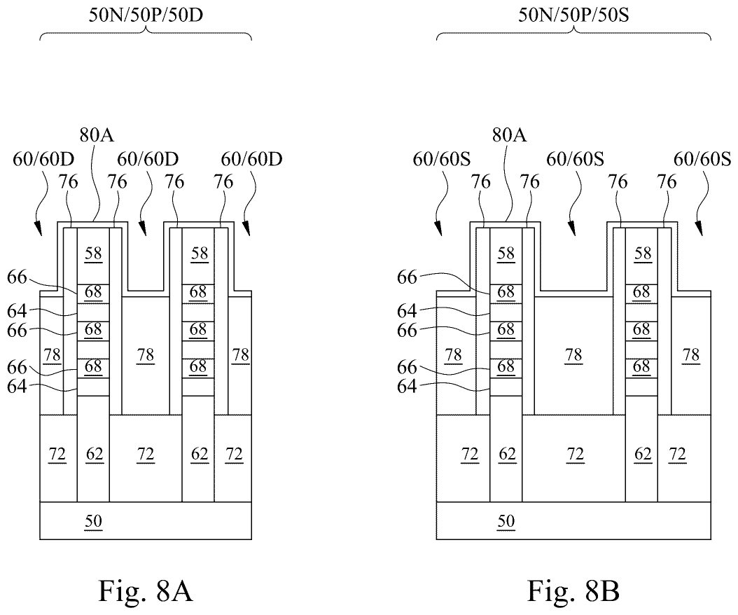

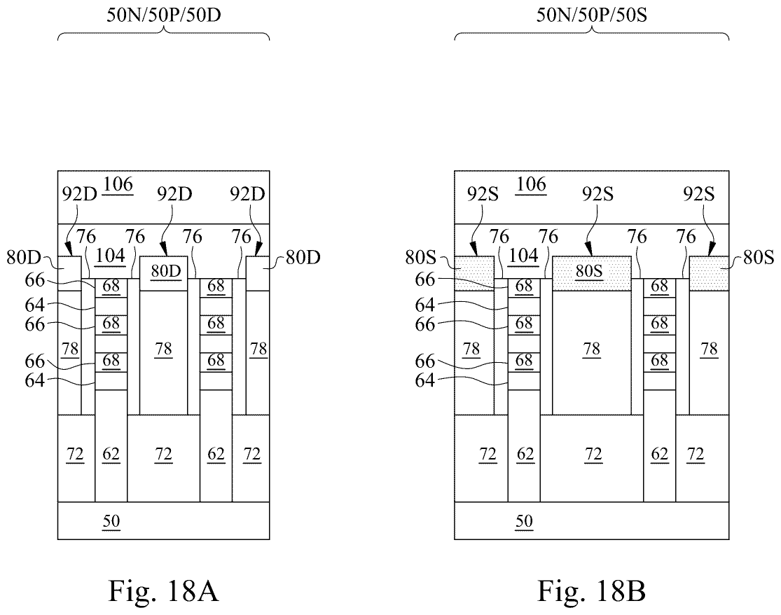

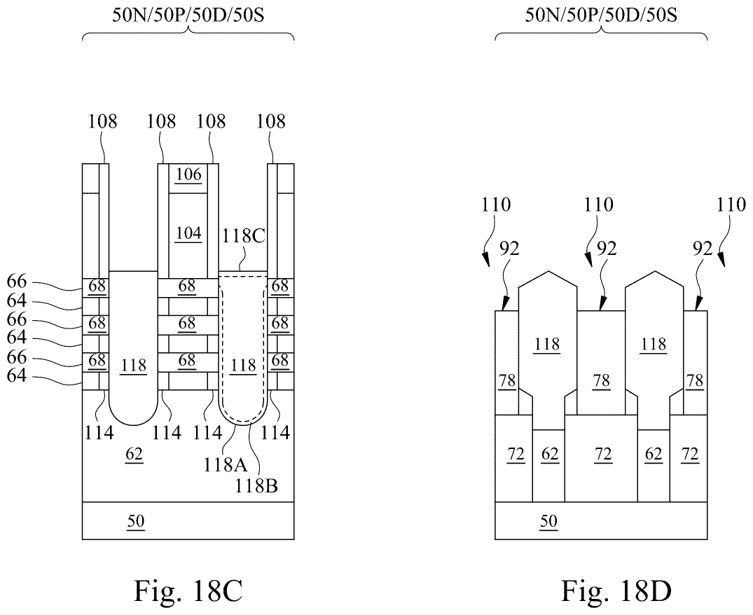

FIGS. 6A-13B illustrate a formation of insulating fins 92 (also referred to as hybrid fins or dielectric fins) between the sacrificial spacers 76 adjacent to the semiconductor fins 62 and nanostructures 64, 66. The insulating fins 92 may insulate and physically separate subsequently formed source/drain regions (see below, FIGS. 18A-18D) from each other. The insulating fins 92 are formed by forming insulating layer(s) 78 (see FIGS. 6A-6B) for lower portions of the insulating fins 92, and then forming insulating layer(s) 80 (see FIGS. 8A-12B) for upper portions of the insulating fins 92. The insulating layer(s) 78 may be referred to as lower insulating layer(s) of the insulating fins 92, and the insulating layer(s) 80 may be referred to as upper insulating layer(s) of the insulating fins 92. The insulating layer(s) 80 are formed of one or more dielectric material(s) having a high etching selectivity from the etching of the insulating layer(s) 78, so that the insulating layer(s) 80 may act as a hard mask to protect the insulating layer(s) 78 during subsequent processing.

In FIGS. 6A-6B, one or more insulating layer(s) 78 for lower portions of insulating fins are formed in the trenches 60. As will be subsequently described, the insulating layer(s) 78 may be formed of one or more dielectric material(s) having a high etching selectivity from the etching of the semiconductor fins 62, the nanostructures 64, 66, and the sacrificial spacers 76. The insulating layer(s) 78 are formed of the same dielectric material in the dense region 50D and the sparse region 50S. In some embodiments, the insulating layer(s) 78 include a liner 78A and a fill material 78B over the liner 78A.

The liner 78A is conformally formed over exposed surfaces of the mask 58, the semiconductor fins 62, the nanostructures 64, 66, the STI regions 72, and the sacrificial spacers 76. In some embodiments, the liner 78A is formed of a nitride such as silicon nitride, silicon carbonitride, silicon oxycarbonitride, or the like, which may be formed by any acceptable deposition process such as atomic layer deposition (ALD), chemical vapor deposition (CVD), physical vapor deposition (PVD), or the like. The liner 78A may reduce oxidation of the sacrificial spacers 76 during the subsequent formation of the fill material 78B, which may be useful for a subsequent removal of the sacrificial spacers 76.

The fill material 78B is conformally formed over the liner 78A, and fills the remaining portions of the trenches 60 which are not filled by the sacrificial spacers 76 or the liner 78A. In some embodiments, the fill material 78B is formed of an oxide such as silicon oxide, silicon oxynitride, silicon oxycarbonitride, silicon oxycarbide, or the like, which may be formed by any acceptable deposition process such as ALD, CVD, PVD, or the like. The fill material 78B may form the bulk of the lower portions of the insulating fins to insulate subsequently formed source/drain regions (see below, FIGS. 18A-18D) from each other.

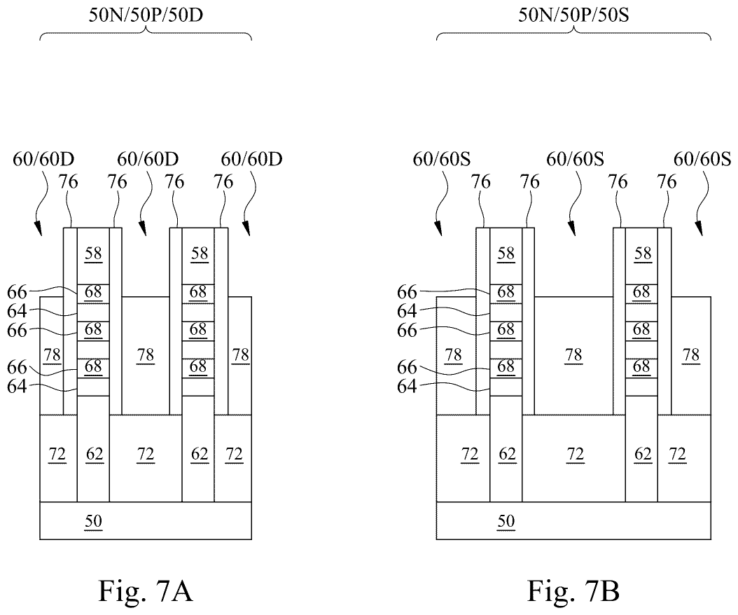

In FIGS. 7A-7B, upper portions of insulating layer(s) 78 above top surfaces of the mask 58 may be removed using one or more acceptable planarization and/or etching processes. The planarization process may be a chemical mechanical polish (CMP), an etch-back process, combinations thereof, or the like. The etching process may be selective to the insulating layer(s) 78 (e.g., selectively etches the materials of the liner 78A and the fill material 78B at a faster rate than the materials of the sacrificial spacers 76 and/or the mask 58). After the etching process, top surfaces of insulating layer(s) 78 are below top surfaces of the mask 58 and the sacrificial spacers 76. The etching process re-forms portions of the trenches 60. The trenches 60S in the sparse region 50S are wider than the trenches 60D in the dense region 50D.

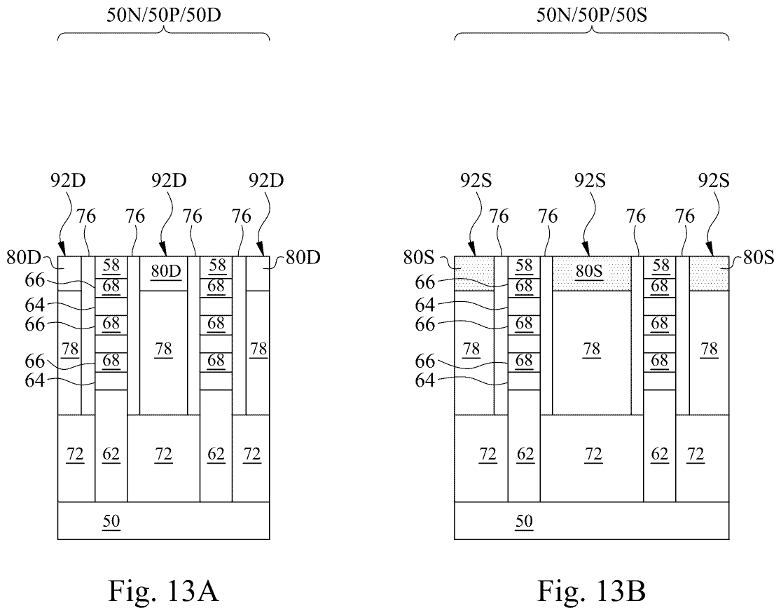

FIGS. 8A-12B illustrate a formation of insulating layer(s) 80 for upper portions of insulating fins in the trenches 60. The insulating layer(s) 80 fill the remaining portions of the trenches 60 which are not filled by the insulating layer(s) 78, and the insulating layer(s) 80S are wider than the insulating layer(s) 80D due to the different widths of the trenches 60D, 60S. The insulating layer(s) 80 (including insulating layer(s) 80D and insulating layer(s) 80S, see FIGS. 13A-13B) are formed of different materials in the dense region 50D and the sparse region 50S. In the illustrated embodiment, the insulating layer(s) 80 are formed of different materials by repeated deposition and conversion processes. Specifically, an insulating layer 80 may be formed by depositing a first dielectric material in the regions 50D, 50S, and then converting at least a portion of the insulating layer 80S in the sparse region 50S to a second dielectric material, while a portion of the insulating layer 80D in the dense region 50D remains the first dielectric material. The deposition and conversion processes may be repeated to build up the insulating layer(s) 80D, 80S in the regions 50D, 50S. A removal process is then applied to remove unconverted portions of the insulating layer(s) 80 (which are formed of the first dielectric material) from the sparse region 50S and to remove converted portions of the insulating layer(s) 80 (which are formed of the second dielectric material) from the dense region 50D. Accordingly, the insulating layer(s) 80D in the dense region 50D are formed of the first dielectric material and the insulating layer(s) 80S in the sparse region 50S are formed of the second dielectric material. Forming the insulating layer(s) 80 of different materials in the dense region 50D and the sparse region 50S allows the insulating layer(s) 80D, 80S in the regions 50D, 50S have a high etching selectivity from the etching of one another.

In FIGS. 8A-8B, a first insulating layer 80A is conformally formed over exposed surfaces of the mask 58, the sacrificial spacers 76, and the insulating layer(s) 78. The first insulating layer 80A is formed of a first dielectric material such as silicon carbide, silicon nitride, silicon oxide, silicon carbonitride, silicon oxycarbonitride, or the like, which may be formed by any acceptable deposition process such as atomic layer deposition (ALD), chemical vapor deposition (CVD), conformal CVD (e.g., flowable CVD), physical vapor deposition (PVD), or the like. In some embodiments, the first insulating layer 80A includes a material under a tensile strain. In some embodiments, the first insulating layer 80A is formed to a thickness in the range of 0.02 nm to 4 nm.

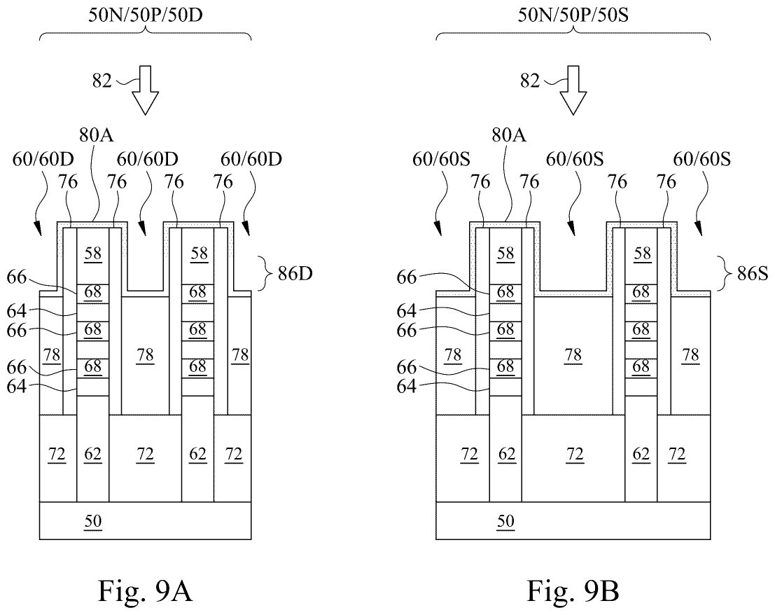

In FIGS. 9A-9B, a portion of the first insulating layer 80A is converted from the first dielectric material to a second dielectric material by a conversion process 82. Converting the first dielectric material to the second dielectric material includes modifying the composition, density, porosity, and/or stress of the first dielectric material. The first dielectric material is different from the second dielectric material, and in this context, the dielectric materials are different when they have different compositions, densities, porosities, and/or stresses. The resulting second dielectric material depends on the first dielectric material and the type of conversion process 82, and will be subsequently described in greater detail. The insulating layer(s) 78 are not modified by the conversion process 82.

More of the first insulating layer 80A in the sparse region 50S is affected by the conversion process 82 than the first insulating layer 80A in the dense region 50D, thereby allowing only portion of the first insulating layer 80A to be modified by the conversion process 82. Specifically, the conversion process 82 is a chemical process, and because the trenches 60S in the sparse region 50S are larger than the trenches 60D in the dense region 50D, the chemical process can more easily penetrate to the bottoms of the trenches 60S than to the bottoms of the trenches 60D, such as due to less crowding in the trenches 60S. As a result, the lower portions 86S of the first insulating layer 80A in the sparse region 50S (e.g., at the bottoms of the trenches 60S) are converted to the second dielectric material, while the lower portions 86D of the first insulating layer 80A in the dense region 50D (e.g., at the bottoms of the trenches 60D) remain as the first dielectric material. Put another way, the conversion process 82 modifies the portions of the first insulating layer 80A in the trenches 60S more than it modifies the portions of the first insulating layer 80A in the trenches 60D. The conversion process 82 may also increase the surface bonding ability of the first insulating layer 80A.

In some embodiments, the conversion process 82 includes modifying the composition of a portion of the first insulating layer 80A. As such, the first dielectric material has a different composition than the second dielectric material. In some embodiments, the first insulating layer 80A is initially formed of silicon carbide, silicon nitride, or silicon oxide, and the conversion process 82 modifies the composition of the converted portion of the first insulating layer 80A so that it is silicon carbonitride, silicon oxycarbide, or silicon oxycarbonitride, respectively. An example of a composition modification process is a radical treatment, in which the converted portion of the first insulating layer 80A is exposed to nitrogen free radicals, oxygen free radicals, or a combination thereof. The radical treatment may be performed in a processing chamber. A gas source is dispensed in the processing chamber. The gas source includes one or more radical precursor gas(es) and a carrier gas. Acceptable radical precursor gases for nitrogen free radicals include nitrogen gas (N₂), ammonia (NH₃), methane (CH₄), combinations thereof, or the like. Acceptable radical precursor gases for oxygen free radicals include carbon dioxide (CO₂), oxygen gas (O₂), combinations thereof, or the like. Acceptable carrier gases include inert gases such as helium (He), xenon (Xe), neon (Ne), krypton (Kr), Radon (Rn), combinations thereof, or the like. A plasma is generated from the gas source. The plasma may be generated by a plasma generator such as a transformer-coupled plasma generator, inductively coupled plasma system, magnetically enhanced reactive ion etching system, electron cyclotron resonance system, remote plasma generator, or the like. The plasma generator generates radio frequency power that produces a plasma from the gas source by applying a voltage above the striking voltage to electrodes in the processing chamber containing the gas source. In some embodiments, the plasma is generated at a pressure in the range of 0.05 Torr to 10.0 Torr (such as in the range of 1 Torr to 2 Torr), at a temperature in the range of 25° C. to 400° C. (such as in the range of 50° C. to 200° C.), and for a duration in the range of 1 second to 10 minutes or in the range of 0.5 seconds to 3 seconds. When the plasma is generated, free radicals (e.g., nitrogen and/or oxygen free radicals) and corresponding ions are generated. The free radicals readily bond with open bonds of silicon atoms of the converted portion of the first insulating layer 80A, thereby nitrating and/or oxidizing the converted portion of the first insulating layer 80A, such that the second dielectric material is composed of more nitrogen or oxygen than the first dielectric material.

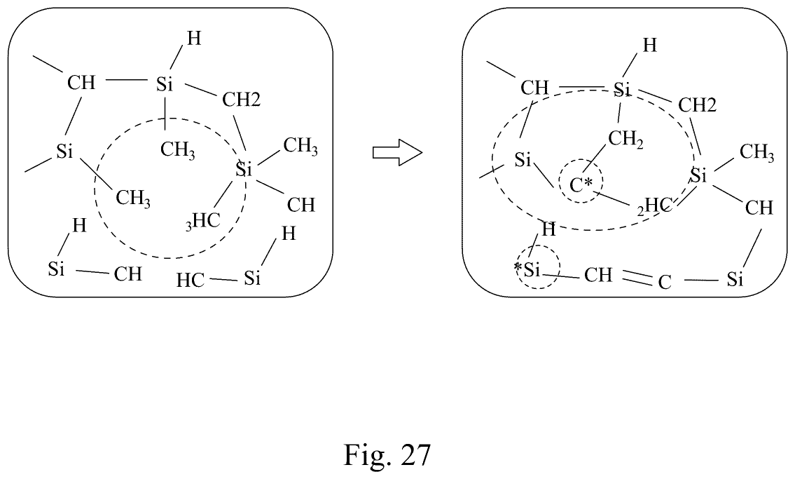

In some embodiments, the conversion process 82 includes modifying the density of a portion of the first insulating layer 80A. As such, the first dielectric material has a different density than the second dielectric material. In some embodiments, the first insulating layer 80A is initially formed of low-density silicon carbide, and the conversion process 82 increases the density of the converted portion of the first insulating layer 80A so that it is high-density silicon carbide. An example of a density modification process is an argon radical treatment, in which the converted portion of the first insulating layer 80A is exposed to argon free radicals. The argon radical treatment may be performed in a processing chamber. A gas source is dispensed in the processing chamber. The gas source includes a radical precursor gas and a carrier gas. Acceptable radical precursor gases for argon free radicals include Ar or the like. Acceptable carrier gases include He, N₂, combinations thereof, or the like. A plasma is generated from the gas source. The plasma may be generated by a plasma generator such as a transformer-coupled plasma generator, inductively coupled plasma system, magnetically enhanced reactive ion etching system, electron cyclotron resonance system, remote plasma generator, or the like. The plasma generator generates radio frequency power that produces a plasma from the gas source by applying a voltage above the striking voltage to electrodes in the processing chamber containing the gas source. When the plasma is generated, free radicals (e.g., argon free radicals) and corresponding ions are generated. The argon free radicals bombard the converted portion of the first insulating layer 80A, thereby densifying the converted portion of the first insulating layer 80A, such that the second dielectric material is denser than the first dielectric material. In some embodiments, the ratio of the density of the second dielectric material to the density of the first dielectric material is about 2.28. FIG. 27 illustrates a reaction when converting a low-density silicon carbide to a high-density silicon carbide. In the reaction, the low-density silicon carbide contains C—H bonds or functional groups, and the conversion process 82 removes hydrogen terminations to cause Si—C—Si crosslinking and form the high-density silicon carbide.

In some embodiments, the conversion process 82 includes modifying the porosity of a portion of the first insulating layer 80A. As such, the first dielectric material has a different porosity than the second dielectric material. In some embodiments, the first insulating layer 80A is initially formed of impermeable silicon carbide, silicon nitride, or silicon oxycarbide, and the conversion process 82 increase the porosity of the converted portion of the first insulating layer 80A so that it is porous silicon carbide, silicon oxide, silicon oxynitride, or silicon oxycarbonitride. An example of a porosity modification process is a anneal process, in which the converted portion of the first insulating layer 80A is annealed while it is exposed to an ambient containing nitrogen and/or oxygen. In some embodiments the anneal process is a dry anneal performed at a temperature in the range of 300° C. to 900° C. using O₂ or N₂ as the process gas, although other process gases may be used. The anneal process drives carbon out of the converted portion of the first insulating layer 80A and/or drives oxygen or nitrogen into the converted portion of the first insulating layer 80A, thereby increasing the porosity of the converted portion of the first insulating layer 80A, such that the second dielectric material is more porous than the first dielectric material.

In some embodiments, the conversion process 82 includes modifying the stress of a portion of the first insulating layer 80A. As such, the first dielectric material is under a different stress than the second dielectric material. In some embodiments, the first insulating layer 80A is initially formed of silicon nitride or silicon carbonitride under a tensile strain, and the conversion process 82 decreases the stress of the converted portion of the first insulating layer 80A so that it is silicon nitride, silicon oxynitride, or silicon oxycarbonitride under a neutral or compressive strain. An example of a stress modification process is a radical treatment, in which the converted portion of the first insulating layer 80A is exposed to argon free radicals or oxygen free radicals. The radical treatment may be performed in a processing chamber. A gas source is dispensed in the processing chamber. The gas source includes a radical precursor gas and a carrier gas. Acceptable radical precursor gases for argon free radicals include argon gas (Ar) or the like. Acceptable radical precursor gases for oxygen free radicals include oxygen gas (O₂) or the like. Acceptable carrier gases include inert gases such as helium (He), xenon (Xe), neon (Ne), krypton (Kr), Radon (Rn), combinations thereof, or the like. A plasma is generated from the gas source. The plasma may be generated by a plasma generator such as a transformer-coupled plasma generator, inductively coupled plasma system, magnetically enhanced reactive ion etching system, electron cyclotron resonance system, remote plasma generator, or the like. The plasma generator generates radio frequency power that produces a plasma from the gas source by applying a voltage above the striking voltage to electrodes in the processing chamber containing the gas source. When the plasma is generated, free radicals (e.g., argon or oxygen free radicals) and corresponding ions are generated. The free radicals bombard the converted portion of the first insulating layer 80A, thereby modifying (e.g., decreasing) the stress of the converted portion of the first insulating layer 80A, such that the first dielectric material is under a tensile strain and the second dielectric material is under a compressive strain. In some embodiments, the first dielectric material has a stress in the range of 0.8 GPa to 1.4 GPa, and the second dielectric material has a stress in the range of −0.2 GPa to 0.2 GPa.

Although each type of conversion process has been separately described, it should be appreciated that a given process may include aspects of several types of conversion processes. For example, a conversion process may modify both the composition and porosity of a portion of the first insulating layer 80A. Similarly, a conversion process may modify both the composition and density of a portion of the first insulating layer 80A.

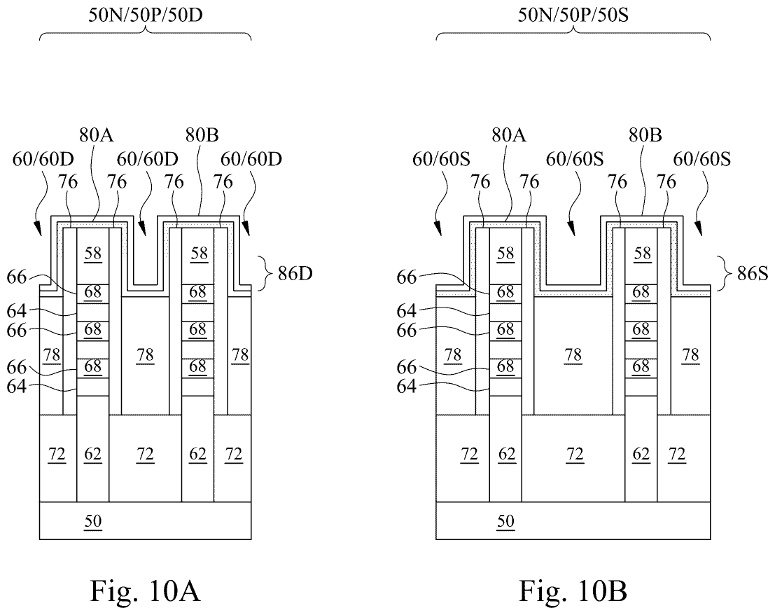

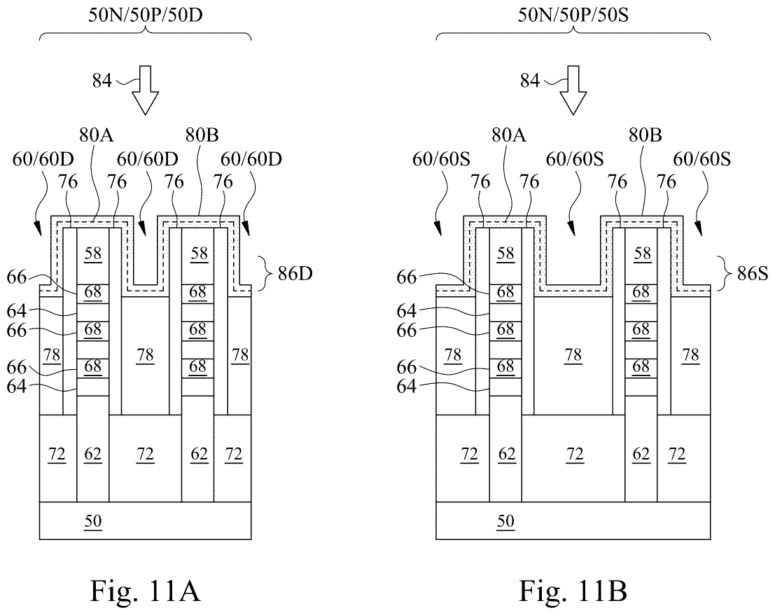

In FIGS. 10A-11B, the steps described for FIGS. 8A-9B are repeated. For example, a second insulating layer 80B is conformally formed over exposed surfaces of the first insulating layer 80A (see FIGS. 10A-10B) and a portion of the second insulating layer 80B is converted from the first dielectric material to a second dielectric material by performing a conversion process 84 (see FIGS. 11A-11B). The second insulating layer 80B is formed of the first dielectric material which the first insulating layer 80A was initially formed of. The second insulating layer 80B maybe be formed to the same thickness as the first insulating layer 80A, or may be formed to a different thickness. In some embodiments, the second insulating layer 80B is formed to a thickness in the range of 0.02 nm to 4 nm. The conversion process 84 may be the same as the conversion process 82, or may be different than the conversion process 82.

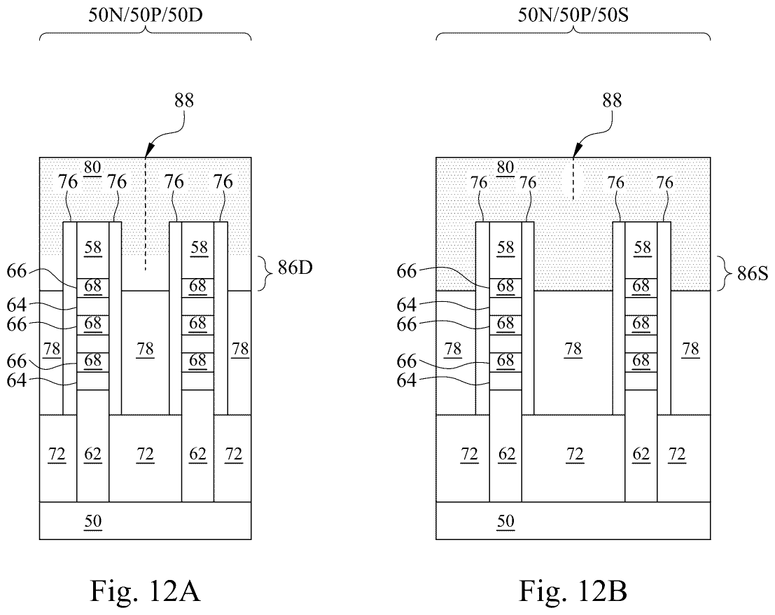

In FIGS. 12A-12B, the steps described for FIGS. 8A-9B are again repeated a desired quantity of times until a desired quantity of the insulating layer(s) 80 have been formed. After formation is complete, the lower portions 86S of the insulating layer(s) 80S in the sparse region 50S (e.g., the portions between the sacrificial spacers 76) are converted to the second dielectric material, while the lower portions 86D of the insulating layer(s) 80 in the dense region 50D (e.g., the portions between the sacrificial spacers 76) remain as the first dielectric material. During formation of the insulating layer(s) 80, they may seam together such that vertical seams 88 are formed. In some areas, such as in the sparse region 50S, the portions of the insulating layer(s) 80 proximate the vertical seams 88 are not converted to the second dielectric material and remain as the first dielectric material. In some embodiments, the process for forming the insulating layer(s) 80 (including the formation of the first dielectric material and the conversion to the second dielectric material) may be performed in the same processing tool (e.g., deposition chamber), without breaking a vacuum in the processing tool between each deposition and conversion step.

In FIGS. 13A-13B, a removal process is applied to the insulating layer(s) 80 to remove excess portions of the insulating layer(s) 80 over the sacrificial spacers 76, the nanostructures 64, 66, and the mask 58. A planarization process such as a chemical mechanical polish (CMP), an etching process, combinations thereof, or the like may be utilized. After the planarization process, top surfaces of the mask 58 and the insulating layer(s) 80 are coplanar (within process variations).

As a result, insulating fins 92 are formed between and contacting the sacrificial spacers 76. The insulating fins 92 include the insulating layer(s) 78 and the insulating layer(s) 80. The insulating layer(s) 78 form the lower portions of the insulating fins 92, and the insulating layer(s) 80 form the upper portions of the insulating fins 92. The sacrificial spacers 76 space the insulating fins 92 apart from the nanostructures 64, 66, and a size of the insulating fins 92 may be adjusted by adjusting a thickness of the sacrificial spacers 76.

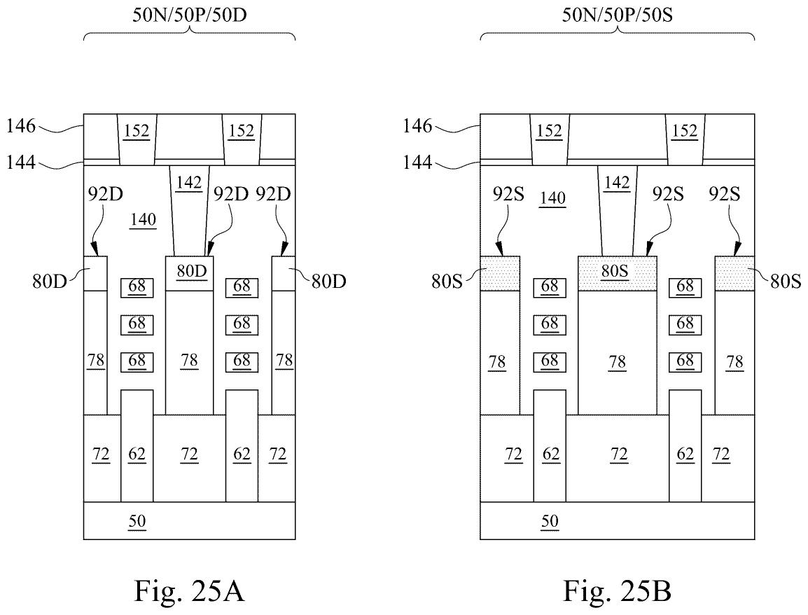

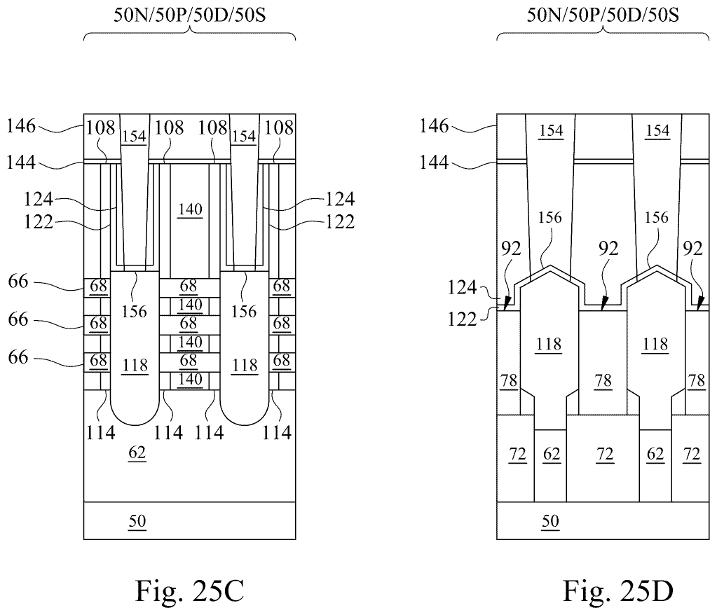

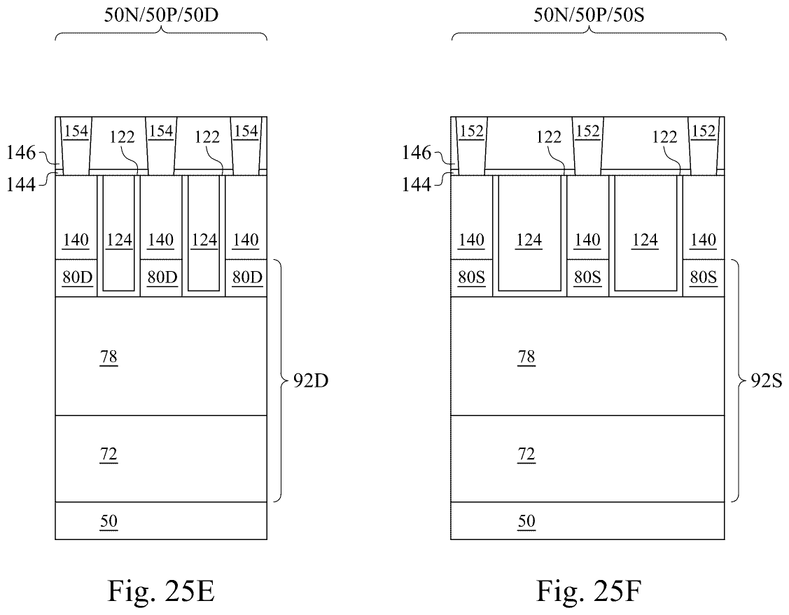

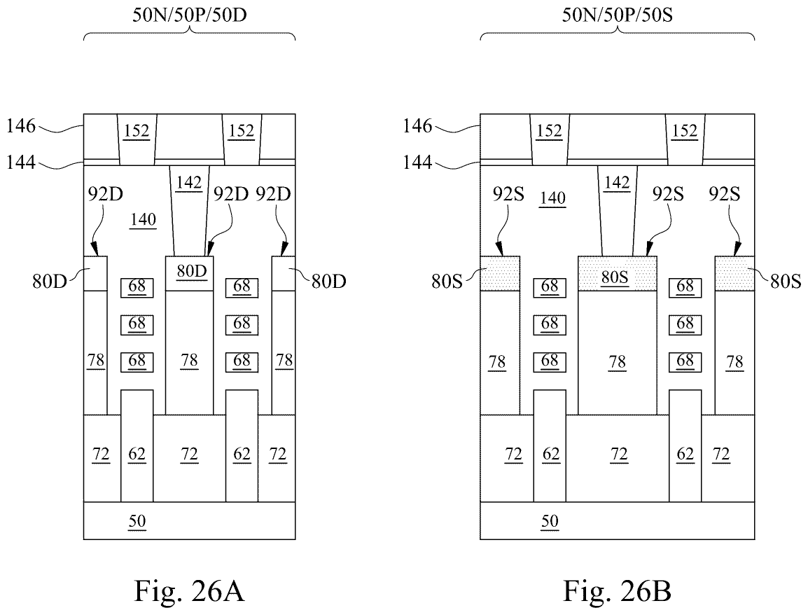

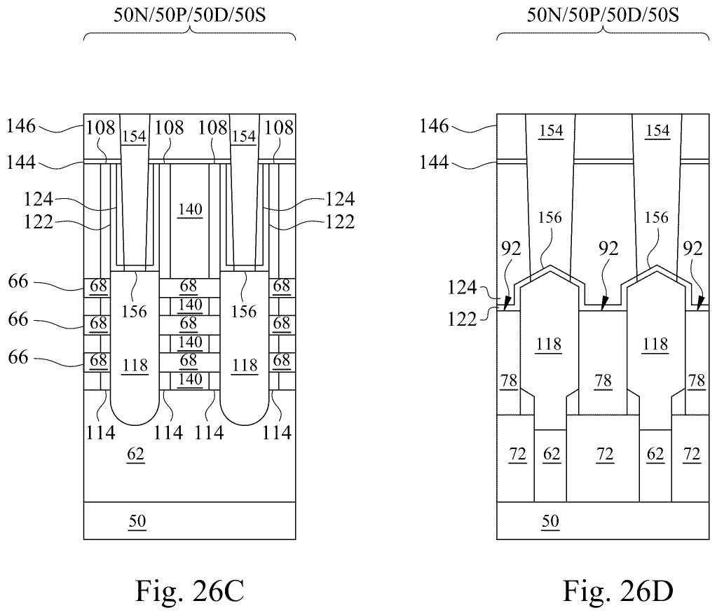

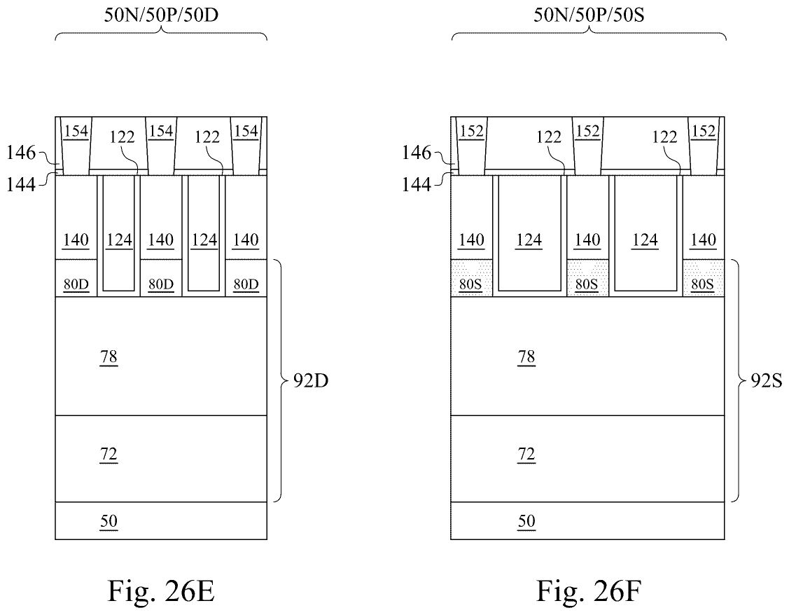

In this embodiment, the removal process is performed until the upper portions of the insulating layer(s) 80 are removed, such that only the lower portions 86D, 86S of the insulating layer(s) 80 remain. As a result, all of the first dielectric material in the sparse region 50S is removed and all of the second dielectric material in the dense region 50D is removed. Accordingly, the insulating fins 92D in the dense region 50D include the insulating layer(s) 80D which are formed of the first dielectric material, and the insulating fins 92S in the sparse region 50S include the insulating layer(s) 80S which are formed of the second dielectric material. In another embodiment (subsequently described for FIGS. 25A-26F), some of the first dielectric material may remain in the sparse region 50S and/or some of the second dielectric material may remain in the dense region 50D after the removal process. In either case, it should be appreciate that a majority of the portions of the insulating layer(s) 80D in the dense region 50D include the first dielectric material, and that a majority of the portions of the insulating layer(s) 80S in the sparse region 50S include the second dielectric material.

In FIGS. 14A-14B, the mask 58 is removed. The mask 58 may be removed using an etching process, for example. The etching process may be a wet etch that selective removes the mask 58 without significantly etching the insulating fins 92. The etching process may be anisotropic. Further, the etching process (or a separate, selective etching process) may also be applied to reduce a height of the sacrificial spacers 76 to a similar level (e.g., same within processing variations) as the nanostructures 64, 66. After the etching process(es), a top surface of the nanostructures 64, 66 and a top surface of the sacrificial spacers 76 may be exposed and may be lower than a top surface of the insulating fins 92.

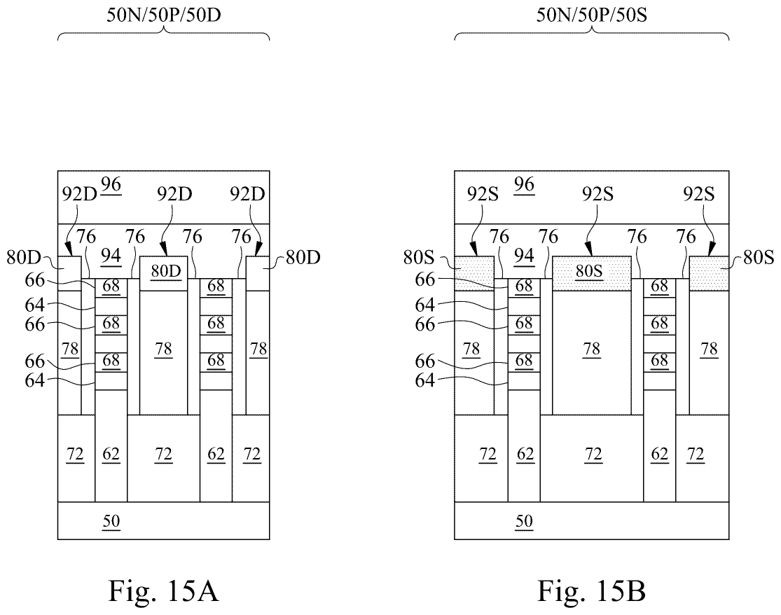

In FIG. 15A-15B, a dummy gate layer 94 is formed on the insulating fins 92, the sacrificial spacers 76, and the nanostructures 64, 66. Because the nanostructures 64, 66 and the sacrificial spacers 76 extend lower than the insulating fins 92, the dummy gate layer 94 may be disposed along exposed sidewalls of the insulating fins 92. The dummy gate layer 94 may be deposited and then planarized, such as by a CMP. The dummy gate layer 94 may be formed of a conductive or non-conductive material, such as amorphous silicon, polycrystalline-silicon (polysilicon), poly-crystalline silicon-germanium (poly-SiGe), a metal, a metallic nitride, a metallic silicide, a metallic oxide, or the like, which may be deposited by physical vapor deposition (PVD), CVD, or the like. The dummy gate layer 94 may also be formed of a semiconductor material (such as one selected from the candidate semiconductor materials of the substrate 50), which may be grown by a process such as vapor phase epitaxy (VPE) or molecular beam epitaxy (MBE), deposited by a process such as chemical vapor deposition (CVD) or atomic layer deposition (ALD), or the like. The dummy gate layer 94 may be formed of material(s) that have a high etching selectivity from the etching of insulation materials, e.g., the insulating fins 92. A mask layer 96 may be deposited over the dummy gate layer 94. The mask layer 96 may be formed of a dielectric material such as silicon nitride, silicon oxynitride, or the like. In this example, a single dummy gate layer 94 and a single mask layer 96 are formed across the n-type region 50N and the p-type region 50P.

In FIGS. 16A-16F, the mask layer 96 is patterned using acceptable photolithography and etching techniques to form masks 106. The pattern of the masks 106 is then transferred to the dummy gate layer 94 by any acceptable etching technique to form dummy gates 104. The dummy gates 104 cover the top surfaces of the nanostructures 64, 66 that will be exposed in subsequent processing to form channel regions. The pattern of the masks 106 may be used to physically separate adjacent dummy gates 104. The dummy gates 104 may also have lengthwise directions substantially perpendicular (within process variations) to the lengthwise directions of the semiconductor fins 62. The masks 106 can optionally be removed after patterning, such as by any acceptable etching technique.

The dummy gates 104, the sacrificial spacers 76, and the nanostructures 64 collectively extend along the portions of the nanostructures 66 that will be patterned to form channel regions 68. Subsequently formed gate structures will replace the dummy gates 104, the sacrificial spacers 76, and the nanostructures 64. Forming the dummy gates 104 over the sacrificial spacers 76 allows the subsequently formed gate structures to have a greater height.

As noted above, the dummy gates 104 may be formed of a semiconductor material. In such embodiments, the nanostructures 64, the sacrificial spacers 76, and the dummy gates 104 are each formed of semiconductor materials. In some embodiments, the nanostructures 64, the sacrificial spacers 76, and the dummy gates 104 are formed of a same semiconductor material (e.g., silicon germanium), so that during a replacement gate process, the nanostructures 64, the sacrificial spacers 76, and the dummy gates 104 may be removed together in a same etching step. In some embodiments, the nanostructures 64 and the sacrificial spacers 76 are formed of a first semiconductor material (e.g., silicon germanium) and the dummy gates 104 are formed of a second semiconductor material (e.g., silicon), so that during a replacement gate process, the dummy gates 104 may be removed in a first etching step, and the nanostructures 64 and the sacrificial spacers 76 may be removed together in a second etching step. In some embodiments, the nanostructures 64 are formed of a first semiconductor material (e.g., silicon germanium) and the sacrificial spacers 76 and the dummy gates 104 are formed of a second semiconductor material (e.g., silicon), so that during a replacement gate process, the sacrificial spacers 76 and the dummy gates 104 may be removed together in a first etching step, and the nanostructures 64 may be removed in a second etching step.

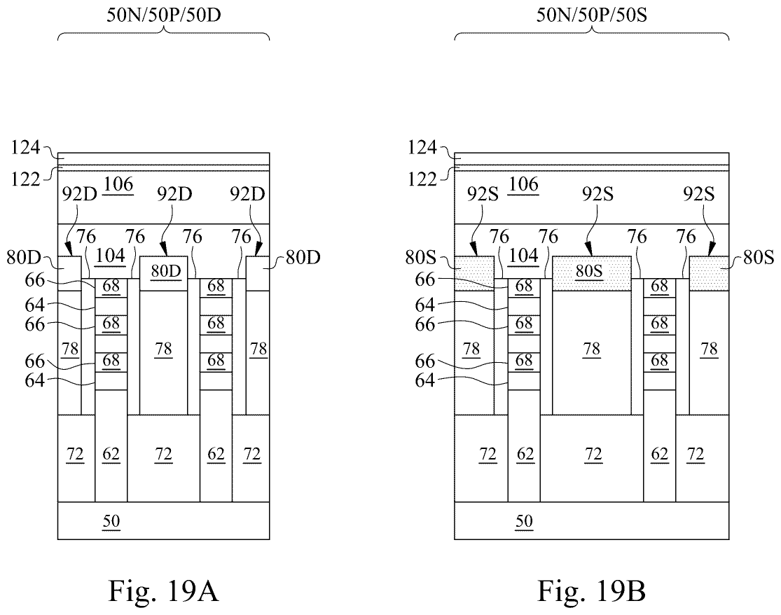

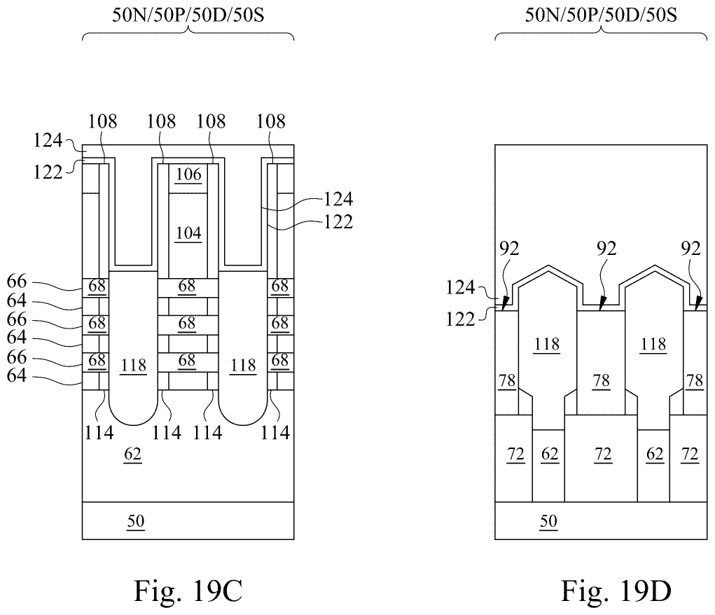

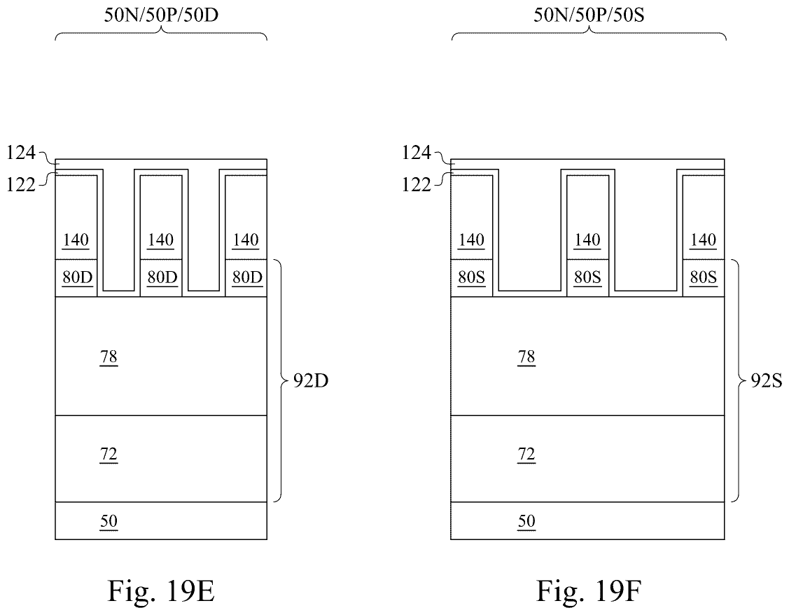

Referring specifically to FIGS. 16E-16F, the pattern of the masks 106 is also transferred to the insulating layer(s) 80 of the insulating fins 92 by any acceptable etching technique to form recesses 110 in portions of the insulating fins 92. The recesses 110 are in the portions of the insulating fins 92 which will disposed between subsequently formed source/drain regions (see below, FIGS. 18A-18D). The recesses 110 will be subsequently filled with an inter-layer dielectric (ILD) (see below, FIGS. 19A-19D). The subsequently formed ILD has a lower relative permittivity than the insulating layer(s) 80, and replacing the portions of the insulating layer(s) 80 between the subsequently formed source/drain regions with a material that provides better electrical isolation may reduce leakage and improve the performance of the resulting nano-FETs.

The insulating layer(s) 80D in the dense region 50D and the insulating layer(s) 80S in the sparse region 50S are patterned by different etching processes when forming the recesses 110. Patterning the insulating layer(s) 80 in the dense region 50D and the sparse region 50S by different etching processes advantageously avoids the use of a single etching process to pattern the insulating layer(s) 80 in both the dense region 50D and the sparse region 50S. Because the features in the dense region 50D are denser than the features in the sparse region 50S, pattern loading would occur if a single etching process were used to pattern the insulating layer(s) 80 in both the dense region 50D and the sparse region 50S, which may result in over-etching of the insulating layer(s) 80S in the sparse region 50S and/or under-etching of the insulating layer(s) 80D in the dense region 50D. Avoiding under-etching and/or over-etching of the insulating layer(s) 80 increase manufacturing yield of the resulting nano-FETs.

As described above, the insulating layer(s) 80 of the insulating fins 92 are formed of different materials in the dense region 50D and the sparse region 50S. Specifically, the insulating layer(s) 80D, 80S have a high etching selectivity from the etching of one another. As a result, the insulating layer(s) 80D, 80S in a respective region 50D, 50S may be patterned without using a mask (such as a photoresist) to cover the other respective region 50D, 50S. Avoiding the use of a mask when patterning the insulating layer(s) 80 may reduce manufacturing costs. The insulating layer(s) 80D, 80S in a respective region 50D, 50S are thus exposed to an etching process used to pattern the recesses 110 in the other respective region 50D, 50S. For example, the recesses 110D in the insulating fins 92D may be patterned by an acceptable etching process, such as one that is selective to the insulating layer(s) 80D (e.g., selectively etches the material(s) of the insulating layer(s) 80D at a faster rate than the material(s) of the insulating layer(s) 80S). Similarly, the recesses 110S in the insulating fins 92S may be patterned by an acceptable etching process, such as one that is selective to the insulating layer(s) 80S (e.g., selectively etches the material(s) of the insulating layer(s) 80S at a faster rate than the material(s) of the insulating layer(s) 80D). The etching processes for patterning the recesses 110D, 110S have different etching parameters. For example, when the first dielectric material of the insulating layer(s) 80D has a different composition than the second dielectric material of the insulating layer(s) 80S, the etching processes may utilize different etchants. In some embodiments, the recesses 110D are patterned by a dry etch performed using a first mixture of argon (Ar), methane (CH₄), a fluorine-based etchant such as hydrogen fluoride (HF), and (optionally) oxygen (O₂) gases as an etchant; the recesses 110S are patterned by a dry etch performed using a second mixture of those same gases as an etchant; and the ratio of the gases in the first mixture is different from the ratio of the gases in the second mixture. The recesses 110S in the sparse region 50S are wider than the recesses 110D in the dense region 50D.

Gate spacers 108 are formed over the nanostructures 64, 66, and on exposed sidewalls of the masks 106 (if present) and the dummy gates 104. The gate spacers 108 may be formed by conformally depositing one or more dielectric material(s) on the dummy gates 104 and subsequently etching the dielectric material(s). Acceptable dielectric materials may include silicon oxide, silicon nitride, silicon oxynitride, silicon oxycarbonitride, or the like, which may be formed by a conformal deposition process such as CVD, ALD, or the like. Other dielectric materials formed by any acceptable process may be used. Any acceptable etching process, such as a dry etch, a wet etch, the like, or a combination thereof, may be performed to pattern the dielectric material(s). The etching may be anisotropic. The dielectric material(s), when etched, have portions left on the sidewalls of the dummy gates 104 (thus forming the gate spacers 108). After etching, the gate spacers 108 can have curved sidewalls or can have straight sidewalls.

Further, implants may be performed to form lightly doped source/drain (LDD) regions (not separately illustrated). In the embodiments with different device types, similar to the implants for the wells previously described, a mask (not separately illustrated) such as a photoresist may be formed over the n-type region 50N, while exposing the p-type region 50P, and appropriate type (e.g., p-type) impurities may be implanted into the semiconductor fins 62 and/or the nanostructures 64, 66 exposed in the p-type region 50P. The mask may then be removed. Subsequently, a mask (not separately illustrated) such as a photoresist may be formed over the p-type region 50P while exposing the n-type region 50N, and appropriate type impurities (e.g., n-type) may be implanted into the semiconductor fins 62 and/or the nanostructures 64, 66 exposed in the n-type region 50N. The mask may then be removed. The n-type impurities may be any of the n-type impurities previously described, and the p-type impurities may be any of the p-type impurities previously described. During the implanting, the channel regions 68 remain covered by the dummy gates 104, so that the channel regions 68 remain substantially free of the impurity implanted to form the LDD regions. The LDD regions may have a concentration of impurities in the range of 10¹⁵ cm⁻³ to 10¹⁹ cm⁻³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

In FIGS. 17A-17D, source/drain recesses 112 are formed in the nanostructures 64, 66 and the sacrificial spacers 76. In the illustrated embodiment, the source/drain recesses 112 extend through the nanostructures 64, 66 and the sacrificial spacers 76 into the semiconductor fins 62. The source/drain recesses 112 may also extend into the substrate 50. In various embodiments, the source/drain recesses 112 may extend to a top surface of the substrate 50 without etching the substrate 50; the semiconductor fins 62 may be etched such that bottom surfaces of the source/drain recesses 112 are disposed below the top surfaces of the STI regions 72; or the like. The source/drain recesses 112 may be formed by etching the nanostructures 64, 66 and the sacrificial spacers 76 using an anisotropic etching process, such as a RIE, a NBE, or the like. The gate spacers 108 and the dummy gates 104 collectively mask portions of the semiconductor fins 62 and/or the nanostructures 64, 66 during the etching processes used to form the source/drain recesses 112. A single etching process may be used to etch each of the nanostructures 64, 66 and the sacrificial spacers 76, or multiple etching processes may be used to etch the nanostructures 64, 66 and the sacrificial spacers 76. Timed etching processes may be used to stop the etching of the source/drain recesses 112 after the source/drain recesses 112 reach a desired depth.

Optionally, inner spacers 114 are formed on the sidewalls of the nanostructures 64, e.g., those sidewalls exposed by the source/drain recesses 112. As will be subsequently described in greater detail, source/drain regions will be subsequently formed in the source/drain recesses 112, and the nanostructures 64 will be subsequently replaced with corresponding gate structures. The inner spacers 114 act as isolation features between the subsequently formed source/drain regions and the subsequently formed gate structures. Further, the inner spacers 114 may be used to substantially prevent damage to the subsequently formed source/drain regions by subsequent etching processes, such as etching processes used to subsequently remove the nanostructures 64.

As an example to form the inner spacers 114, the source/drain recesses 112 can be laterally expanded. Specifically, portions of the sidewalls of the nanostructures 64 exposed by the source/drain recesses 112 may be recessed. Although sidewalls of the nanostructures 64 are illustrated as being straight, the sidewalls may be concave or convex. The sidewalls may be recessed by any acceptable etching process, such as one that is selective to the nanostructures 64 (e.g., selectively etches the materials of the nanostructures 64 at a faster rate than the material of the nanostructures 66). The etching may be isotropic. For example, when the nanostructures 66 are formed of silicon and the nanostructures 64 are formed of silicon germanium, the etching process may be a wet etch performed using tetramethylammonium hydroxide (TMAH), ammonium hydroxide (NH₄OH), or the like as an etchant. In another embodiment, the etching process may be a dry etch performed using a fluorine-based gas such as hydrogen fluoride (HF) gas as an etchant. In some embodiments, the same etching process may be continually performed to both form the source/drain recesses 112 and recess the sidewalls of the nanostructures 64. The inner spacers 114 are then formed on the recessed sidewalls of the nanostructures 64. The inner spacers 114 can be formed by conformally forming an insulating material and subsequently etching the insulating material. The insulating material may be silicon nitride or silicon oxynitride, although any suitable material, such as a low-k dielectric material, may be utilized. The insulating material may be deposited by a conformal deposition process, such as ALD, CVD, or the like. The etching of the insulating material may be anisotropic. For example, the etching process may be a dry etch such as a RIE, a NBE, or the like. Although outer sidewalls of the inner spacers 114 are illustrated as being flush with respect to the sidewalls of the gate spacers 108, the outer sidewalls of the inner spacers 114 may extend beyond or be recessed from the sidewalls of the gate spacers 108. In other words, the inner spacers 114 may partially fill, completely fill, or overfill the sidewall recesses. Moreover, although the sidewalls of the inner spacers 114 are illustrated as being straight, the sidewalls of the inner spacers 114 may be concave or convex.

In FIGS. 18A-18D, epitaxial source/drain regions 118 are formed in the source/drain recesses 112. The epitaxial source/drain regions 118 are formed in the source/drain recesses 112 such that each dummy gate 104 (and corresponding channel region 68) is disposed between respective adjacent pairs of the epitaxial source/drain regions 118. In some embodiments, the gate spacers 108 and the inner spacers 114 are used to separate the epitaxial source/drain regions 118 from, respectively, the dummy gates 104 and the nanostructures 64 by an appropriate lateral distance so that the epitaxial source/drain regions 118 do not short out with subsequently formed gates of the resulting nano-FETs. A material of the epitaxial source/drain regions 118 may be selected to exert stress in the respective channel regions 68, thereby improving performance.

The epitaxial source/drain regions 118 in the n-type region 50N may be formed by masking the p-type region 50P. Then, the epitaxial source/drain regions 118 in the n-type region 50N are epitaxially grown in the source/drain recesses 112 in the n-type region 50N. The epitaxial source/drain regions 118 may include any acceptable material appropriate for n-type devices. For example, if the nanostructures 66 are silicon, the epitaxial source/drain regions 118 in the n-type region 50N may include materials exerting a tensile strain on the channel regions 68, such as silicon, silicon carbide, phosphorous doped silicon carbide, silicon arsenide, silicon phosphide, or the like. The epitaxial source/drain regions 118 in the n-type region 50N may be referred to as “n-type source/drain regions.” The epitaxial source/drain regions 118 in the n-type region 50N may have surfaces raised from respective surfaces of the semiconductor fins 62 and the nanostructures 64, 66, and may have facets.

The epitaxial source/drain regions 118 in the p-type region 50P may be formed by masking the n-type region 50N. Then, the epitaxial source/drain regions 118 in the p-type region 50P are epitaxially grown in the source/drain recesses 112 in the p-type region 50P. The epitaxial source/drain regions 118 may include any acceptable material appropriate for p-type devices. For example, if the nanostructures 66 are silicon, the epitaxial source/drain regions 118 in the p-type region 50P may include materials exerting a compressive strain on the channel regions 68, such as silicon germanium, boron doped silicon germanium, silicon germanium phosphide, germanium, germanium tin, or the like. The epitaxial source/drain regions 118 in the p-type region 50P may be referred to as “p-type source/drain regions.” The epitaxial source/drain regions 118 in the p-type region 50P may have surfaces raised from respective surfaces of the semiconductor fins 62 and the nanostructures 64, 66, and may have facets.

The epitaxial source/drain regions 118, the nanostructures 64, 66, and/or the semiconductor fins 62 may be implanted with impurities to form source/drain regions, similar to the process previously described for forming LDD regions, followed by an anneal. The epitaxial source/drain regions 118 may have an impurity concentration in the range of 10¹⁹ cm⁻³ to 10²¹ cm⁻³. The n-type and/or p-type impurities for source/drain regions may be any of the impurities previously described. In some embodiments, the epitaxial source/drain regions 118 may be in situ doped during growth.

The epitaxial source/drain regions 118 may include one or more semiconductor material layers. For example, the epitaxial source/drain regions 118 may each include a liner layer 118A, a main layer 118B, and a finishing layer 118C (or more generally, a first semiconductor material layer, a second semiconductor material layer, and a third semiconductor material layer). Any number of semiconductor material layers may be used for the epitaxial source/drain regions 118. Each of the liner layer 118A, the main layer 118B, and the finishing layer 118C may be formed of different semiconductor materials and may be doped to different impurity concentrations. In some embodiments, the liner layer 118A may have a lesser concentration of impurities than the main layer 118B, and the finishing layer 118C may have a greater concentration of impurities than the liner layer 118A and a lesser concentration of impurities than the main layer 118B. In embodiments in which the epitaxial source/drain regions include three semiconductor material layers, the liner layers 118A may be grown in the source/drain recesses 112, the main layers 118B may be grown on the liner layers 118A, and the finishing layers 118C may be grown on the main layers 118B.

As a result of the epitaxy processes used to form the epitaxial source/drain regions 118, upper surfaces of the epitaxial source/drain regions have facets which expand laterally outward beyond sidewalls of the semiconductor fins 62 and the nanostructures 64, 66. However, the insulating fins 92 (where present) block the lateral epitaxial growth. Therefore, adjacent epitaxial source/drain regions 118 remain separated after the epitaxy process is completed as illustrated by FIG. 18D. The epitaxial source/drain regions 118 contact the sidewalls of the insulating fins 92. In the illustrated embodiment, the epitaxial source/drain regions 118 are grown so that the upper surfaces of the epitaxial source/drain regions 118 are disposed below the top surfaces of the insulating fins 92. In various embodiments, the upper surfaces of the epitaxial source/drain regions 118 are disposed above the top surfaces of the insulating fins 92; the upper surfaces of the epitaxial source/drain regions 118 have portions disposed above and below the top surfaces of the insulating fins 92; or the like.

In FIGS. 19A-19F, a first ILD 124 is deposited over the epitaxial source/drain regions 118, the gate spacers 108, the masks 106 (if present) or the dummy gates 104. The first ILD 124 may be formed of a dielectric material, which may be deposited by any suitable method, such as CVD, plasma-enhanced CVD (PECVD), FCVD, or the like. Acceptable dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a contact etch stop layer (CESL) 122 is formed between the first ILD 124 and the epitaxial source/drain regions 118, the gate spacers 108, and the masks 106 (if present) or the dummy gates 104. The CESL 122 may be formed of a dielectric material having a high etching selectivity from the etching of the first ILD 124, such as silicon nitride, silicon oxide, silicon oxynitride, or the like, which may be formed by any suitable method, such as CVD, ALD, or the like.

Referring specifically to FIGS. 19E-19F, the CESL 122 and the first ILD 124 are formed in the recesses 110 (see FIGS. 16E-16F and 18D). As such, the CESL 122 and the first ILD 124 extend into a portion of the insulating fins 92 (e.g., through the insulating layer(s) 80 of the insulating fins 92). The insulating fins 92 and portions of the CESL 122 and the first ILD 124 thus collectively separate adjacent epitaxial source/drain regions 118 (see also, FIG. 19D) from each other. The dielectric materials of the CESL 122 and the first ILD 124 provide better electrical isolation than the material(s) of the insulating layer(s) 80 they replaced. As such, leakage between adjacent epitaxial source/drain regions 118 may be reduced, thereby improving the performance of the resulting nano-FETs.

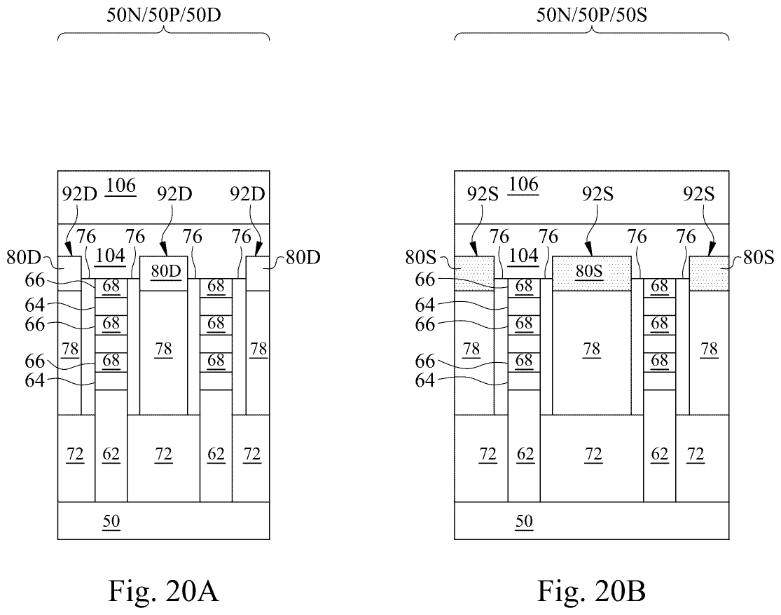

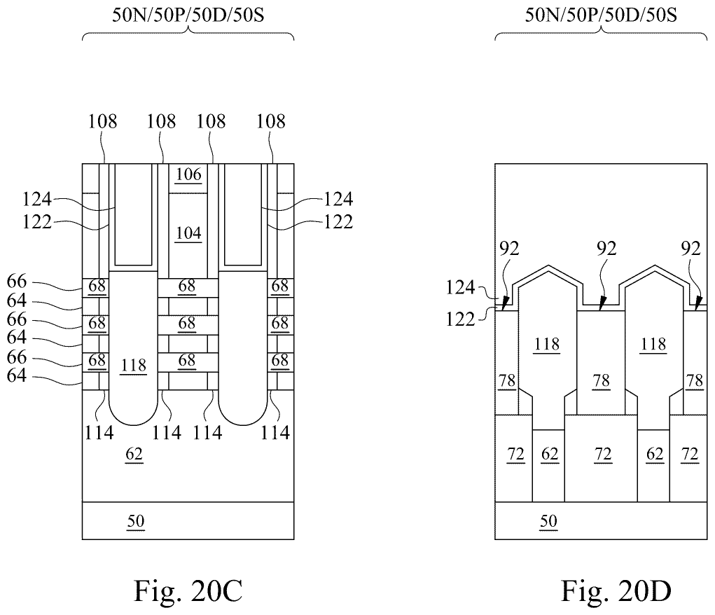

In FIGS. 20A-20D, a removal process is performed to level the top surfaces of the first ILD 124 with the top surfaces of the masks 106 (if present) or the dummy gates 104. In some embodiments, a planarization process such as a chemical mechanical polish (CMP), an etch-back process, combinations thereof, or the like may be utilized. The planarization process may also remove the masks 106 on the dummy gates 104, and portions of the gate spacers 108 along sidewalls of the masks 106. After the planarization process, the top surfaces of the gate spacers 108, the first ILD 124, the CESL 122, and the masks 106 (if present) or the dummy gates 104 are coplanar (within process variations). Accordingly, the top surfaces of the masks 106 (if present) or the dummy gates 104 are exposed through the first ILD 124. In the illustrated embodiment, the masks 106 remain, and the planarization process levels the top surfaces of the first ILD 124 with the top surfaces of the masks 106.

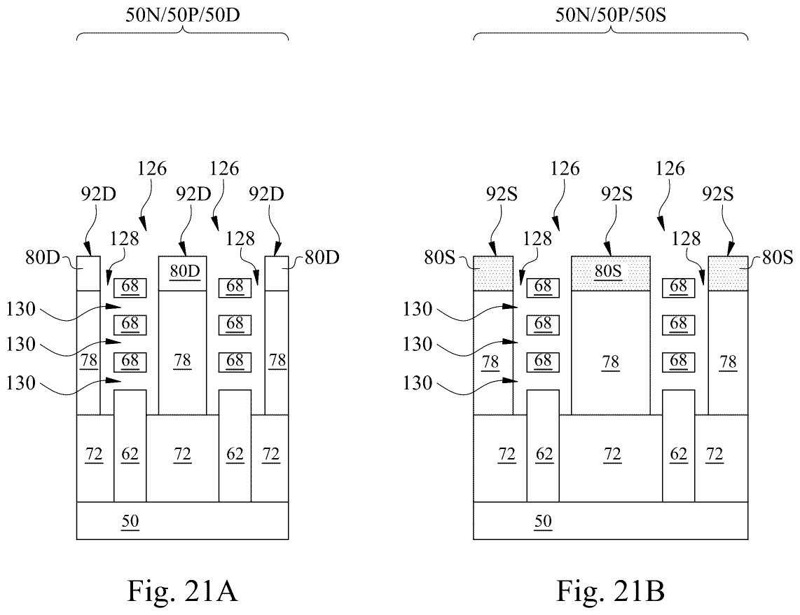

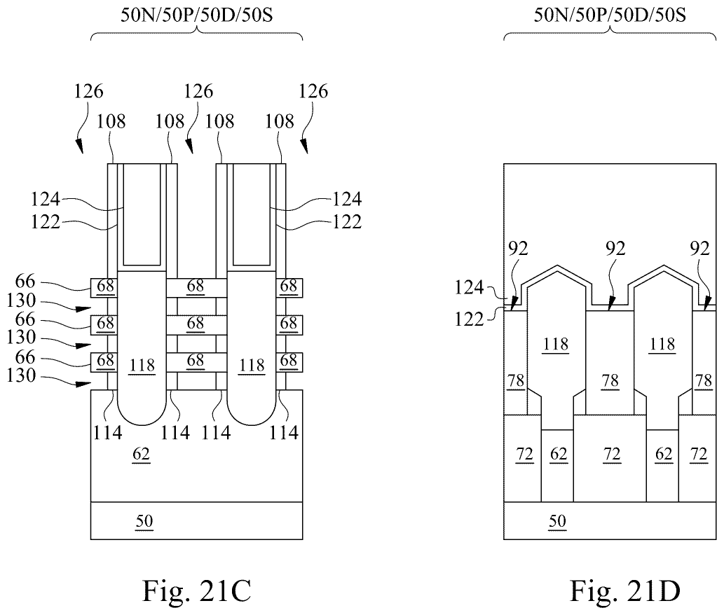

In FIGS. 21A-21D, the masks 106 (if present) and the dummy gates 104 are removed in an etching process, so that recesses 126 are formed. In some embodiments, the dummy gates 104 are removed by an anisotropic etching process. For example, the etching process may include a dry etching performed using reaction gas(es) that selectively etch the dummy gates 104 at a faster rate than the first ILD 124 or the gate spacers 108. Each recess 126 exposes and/or overlies portions of the channel regions 68. Portions of the nanostructures 66 which act as the channel regions 68 are disposed between adjacent pairs of the epitaxial source/drain regions 118.

The remaining portions of the sacrificial spacers 76 are then removed to expand the recesses 126, such that openings 128 are formed in regions between semiconductor fins 62 and the insulating fins 92. The remaining portions of the nanostructures 64 are also removed to expand the recesses 126, such that openings 130 are formed in regions between the nanostructures 66. The remaining portions of the nanostructures 64 and the sacrificial spacers 76 can be removed by any acceptable etching process that selectively etches the material(s) of the nanostructures 64 and the sacrificial spacers 76 at a faster rate than the material of the nanostructures 66. The etching may be isotropic. For example, when the nanostructures 64 and the sacrificial spacers 76 are formed of silicon germanium and the nanostructures 66 are formed of silicon, the etching process may be a wet etch performed using tetramethylammonium hydroxide (TMAH), ammonium hydroxide (NH₄OH), or the like as an etchant. In some embodiments, a trim process (not separately illustrated) is performed to decrease the thicknesses of the exposed portions of the nanostructures 66.

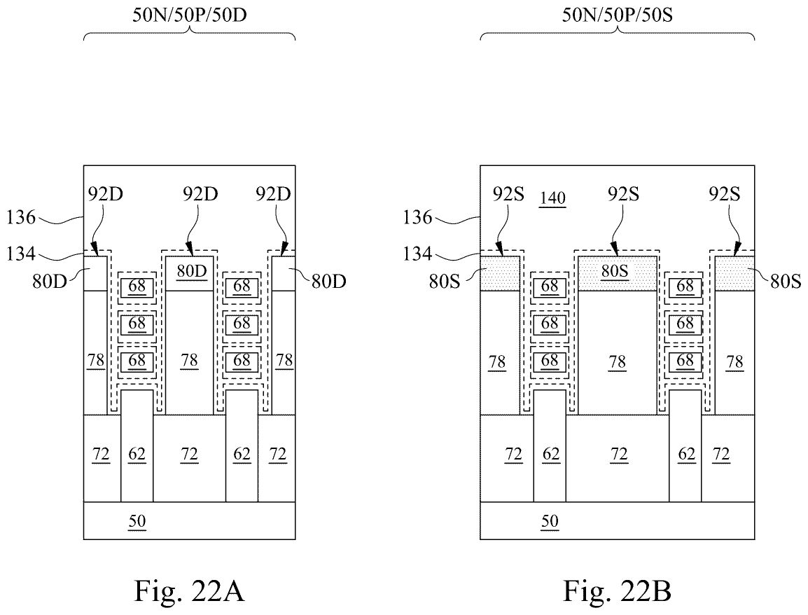

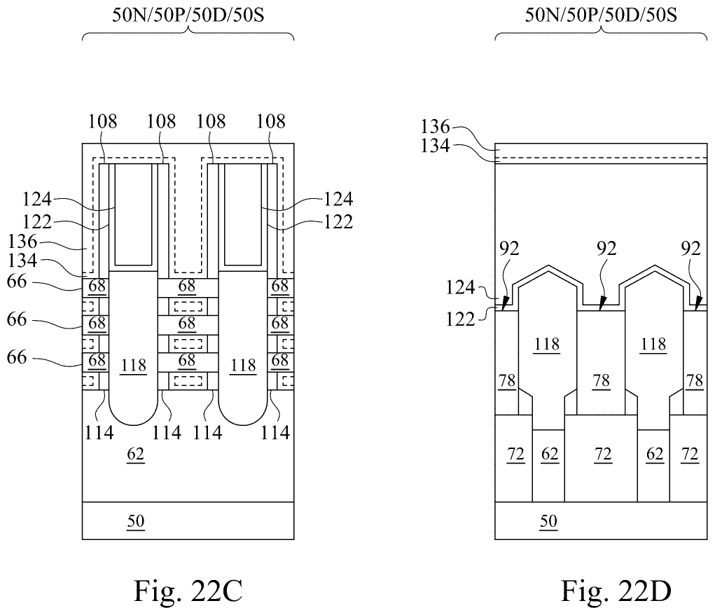

In FIGS. 22A-22D, a gate dielectric layer 134 is formed in the recesses 126. A gate electrode layer 136 is formed on the gate dielectric layer 134. The gate dielectric layer 134 and the gate electrode layer 136 are layers for replacement gates, and each wrap around all (e.g., four) sides of the nanostructures 66. Thus, the gate dielectric layer 134 and the gate electrode layer 136 are formed in the openings 128, 130 (see FIGS. 21A-21C).

The gate dielectric layer 134 is disposed on the sidewalls and/or the top surfaces of the semiconductor fins 62; on the top surfaces, the sidewalls, and the bottom surfaces of the nanostructures 66; on the sidewalls of the inner spacers 114 adjacent the epitaxial source/drain regions 118 and the gate spacers 108 on top surfaces of the inner spacers 114; and on the top surfaces and the sidewalls of the insulating fins 92. The gate dielectric layer 134 may also be formed on the top surfaces of the first ILD 124 and the gate spacers 108. The gate dielectric layer 134 may include an oxide such as silicon oxide or a metal oxide, a silicate such as a metal silicate, combinations thereof, multi-layers thereof, or the like. The gate dielectric layer 134 may include a high-k dielectric material (e.g., a dielectric material having a k-value greater than about 7.0), such as a metal oxide or a silicate of hafnium, aluminum, zirconium, lanthanum, manganese, barium, titanium, lead, and combinations thereof. Although a single-layered gate dielectric layer 134 is illustrated in FIGS. 22A-22D, the gate dielectric layer 134 may include any number of interfacial layers and any number of main layers.

The gate electrode layer 136 may include a metal-containing material such as titanium nitride, titanium oxide, tungsten, cobalt, ruthenium, aluminum, combinations thereof, multi-layers thereof, or the like. Although a single-layered gate electrode layer 136 is illustrated in FIGS. 22A-22D, the gate electrode layer 136 may include any number of work function tuning layers, any number of barrier layers, any number of glue layers, and a fill material.

The formation of the gate dielectric layers 134 in the n-type region 50N and the p-type region 50P may occur simultaneously such that the gate dielectric layers 134 in each region are formed of the same materials, and the formation of the gate electrode layers 136 may occur simultaneously such that the gate electrode layers 136 in each region are formed of the same materials. In some embodiments, the gate dielectric layers 134 in each region may be formed by distinct processes, such that the gate dielectric layers 134 may be different materials and/or have a different number of layers, and/or the gate electrode layers 136 in each region may be formed by distinct processes, such that the gate electrode layers 136 may be different materials and/or have a different number of layers. Various masking steps may be used to mask and expose appropriate regions when using distinct processes.

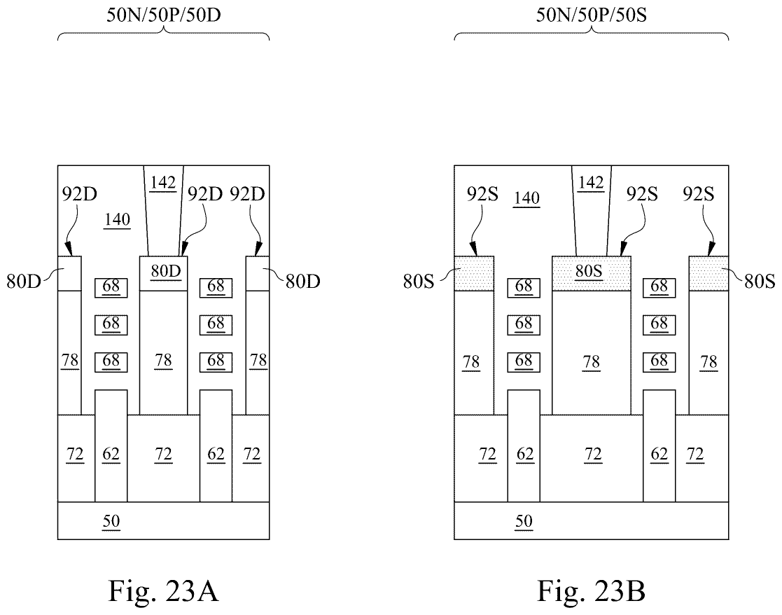

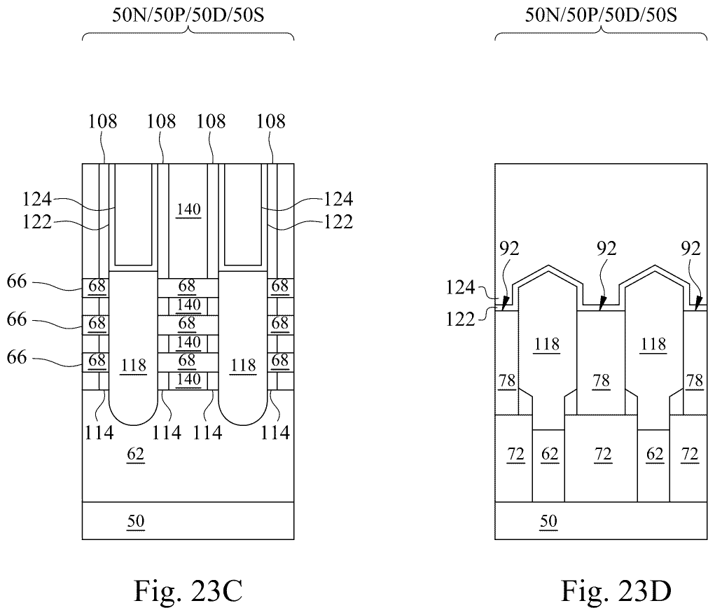

In FIGS. 23A-23D, a removal process is performed to remove the excess portions of the materials of the gate dielectric layer 134 and the gate electrode layer 136, which excess portions are over the top surfaces of the first ILD 124 and the gate spacers 108, thereby forming gate structures 140. In some embodiments, a planarization process such as a chemical mechanical polish (CMP), an etch-back process, combinations thereof, or the like may be utilized. The gate dielectric layer 134, when planarized, has portions left in the recesses 126 (thus forming gate dielectrics for the gate structures 140). The gate electrode layer 136, when planarized, has portions left in the recesses 126 (thus forming gate electrodes for the gate structures 140). The top surfaces of the gate spacers 108; the CESL 122; the first ILD 124; and the gate structures 140 are coplanar (within process variations). The gate structures 140 are replacement gates of the resulting nano-FETs, and may be referred to as “metal gates.” The gate structures 140 each extend along top surfaces, sidewalls, and bottom surfaces of a channel region 68 of the nanostructures 66. Additionally, the gate structures 140 each extend along top surfaces of the insulating layer(s) 80 for the insulating fins 92, and along sidewalls of the insulating layer(s) 78, 80 for the insulating fins 92. The gate structures 140 fill the area previously occupied by the nanostructures 64, the sacrificial spacers 76, and the dummy gates 104.

In some embodiments, isolation regions 142 are formed extending through some of the gate structures 140. An isolation region 142 is formed to divide (or “cut”) a gate structure 140 into multiple gate structures 140. The isolation region 142 may be formed of a dielectric material, such as silicon nitride, silicon oxide, silicon oxynitride, or the like, which may be formed by a deposition process such as CVD, ALD, or the like. As an example to form the isolation regions 142, openings can be patterned in the desired gate structures 140. Any acceptable etching process, such as a dry etch, a wet etch, the like, or a combination thereof, may be performed to pattern the openings. The etching may be anisotropic. One or more layers of dielectric material may be deposited in the openings. A removal process may be performed to remove the excess portions of the dielectric material, which excess portions are over the top surfaces of the gate structures 140, thereby forming the isolation regions 142.

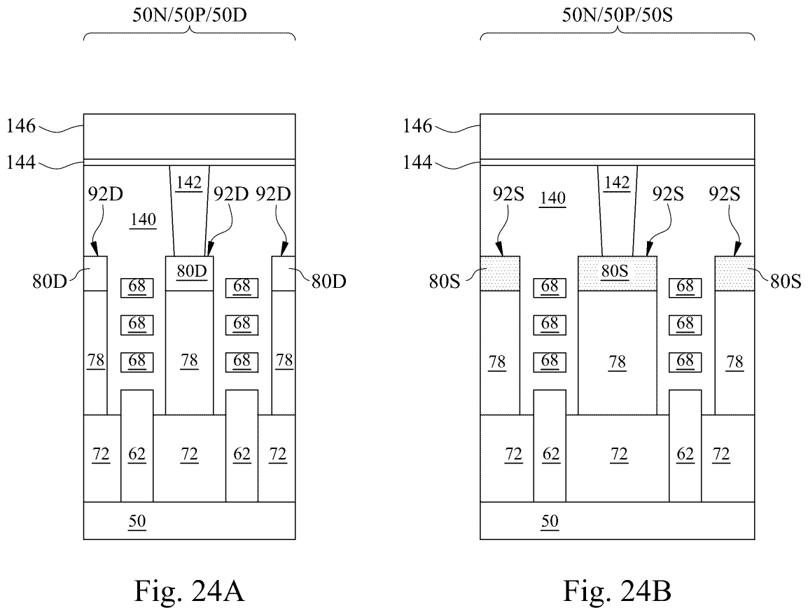

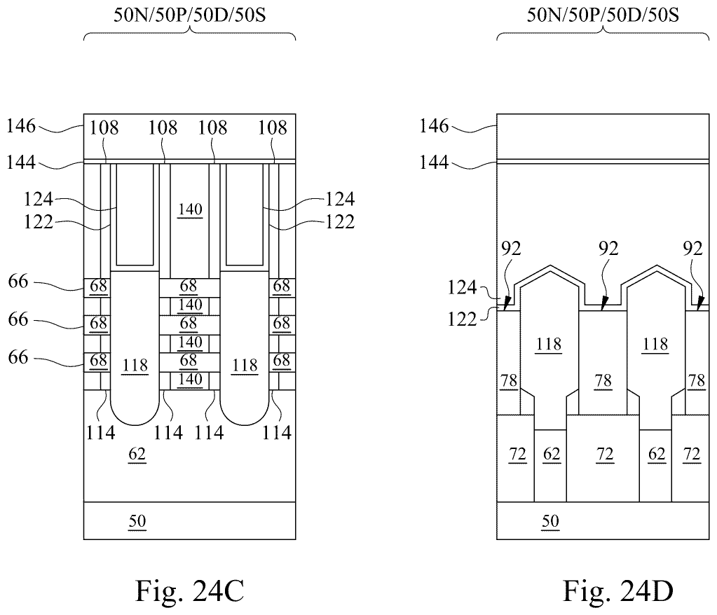

In FIGS. 24A-24D, a second ILD 146 is deposited over the gate spacers 108, the CESL 122, the first ILD 124, and the gate structures 140. In some embodiments, the second ILD 146 is a flowable film formed by a flowable CVD method. In some embodiments, the second ILD 146 is formed of a dielectric material such as PSG, BSG, BPSG, USG, or the like, which may be deposited by any suitable method, such as CVD, PECVD, or the like.

In some embodiments, an etch stop layer (ESL) 144 is formed between the second ILD 146 and the gate spacers 108, the CESL 122, the first ILD 124, and the gate structures 140. The ESL 144 may include a dielectric material, such as silicon nitride, silicon oxide, silicon oxynitride, or the like, having a high etching selectivity from the etching of the second ILD 146.

In FIGS. 25A-25F, gate contacts 152 and source/drain contacts 154 are formed to contact, respectively, the gate structures 140 and the epitaxial source/drain regions 118. The gate contacts 152 are physically and electrically coupled to the gate structures 140. The source/drain contacts 154 are physically and electrically coupled to the epitaxial source/drain regions 118.

As an example to form the gate contacts 152 and the source/drain contacts 154, openings for the gate contacts 152 are formed through the second ILD 146 and the ESL 144, and openings for the source/drain contacts 154 are formed through the second ILD 146, the ESL 144, the first ILD 124, and the CESL 122. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 146. The remaining liner and conductive material form the gate contacts 152 and the source/drain contacts 154 in the openings. The gate contacts 152 and the source/drain contacts 154 may be formed in distinct processes, or may be formed in the same process. Although shown as being formed in the same cross-sections, it should be appreciated that each of the gate contacts 152 and the source/drain contacts 154 may be formed in different cross-sections, which may avoid shorting of the contacts.

Optionally, metal-semiconductor alloy regions 156 are formed at the interfaces between the epitaxial source/drain regions 118 and the source/drain contacts 154. The metal-semiconductor alloy regions 156 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 156 can be formed before the material(s) of the source/drain contacts 154 by depositing a metal in the openings for the source/drain contacts 154 and then performing a thermal anneal process. The metal can be any metal capable of reacting with the semiconductor materials (e.g., silicon, silicon-germanium, germanium, etc.) of the epitaxial source/drain regions 118 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 154, such as from surfaces of the metal-semiconductor alloy regions 156. The material(s) of the source/drain contacts 154 can then be formed on the metal-semiconductor alloy regions 156.

Embodiments may achieve advantages. Depositing the insulating layer(s) 80 for the insulating fins 92 as a first dielectric material in the regions 50D, 50S and then converting a portion of the insulating layer(s) 80 in the sparse region 50S to a second dielectric material allows the resulting insulating fins 92D, 92S to have upper portions formed of different dielectric materials. As such, the upper portions of the insulating fins 92D, 92S have a high etching selectivity from the etching of one another, thereby allowing the insulating fins 92D, 92S in a respective region 50D, 50S to be etched without using a mask (such as a photoresist) to cover the other respective region 50D, 50S. Separate etching processes may thus be used to pattern the insulating fins 92D, 92S, thereby avoiding pattern loading effects, without incurring the costs of using a mask. Replacing a portion of the insulating layer(s) 80 of the insulating fins 92 with material(s) that provide better electrical isolation between adjacent epitaxial source/drain regions 118 can reduce leakage, thereby improving the performance of the resulting nano-FETs.

FIGS. 26A-26F are views of nano-FETs, in accordance with some other embodiments. In this embodiment, some of the first dielectric material remains in the sparse region 50S after the removal process described for FIGS. 13A-13B. Although some of the insulating layer(s) 80S of the insulating fins 92S contain some of the first dielectric material, a majority of the insulating layer(s) 80S of the insulating fins 92S contain the second dielectric material. Therefore, a desired etching selectivity between the insulating layer(s) 80D, 80S may still be achieved.

In an embodiment, a device includes: first source/drain regions; a first insulating fin between the first source/drain regions, the first insulating fin including a first lower insulating layer and a first upper insulating layer; second source/drain regions; and a second insulating fin between the second source/drain regions, the second insulating fin including a second lower insulating layer and a second upper insulating layer, the first lower insulating layer and the second lower insulating layer including the same dielectric material, the first upper insulating layer and the second upper insulating layer including different dielectric materials. In some embodiments of the device, the first upper insulating layer includes a first dielectric material, the second upper insulating layer includes a second dielectric material, and the first dielectric material has a different composition than the second dielectric material. In some embodiments of the device, the first upper insulating layer includes a first dielectric material, the second upper insulating layer includes a second dielectric material, and the first dielectric material has a different density than the second dielectric material. In some embodiments of the device, the first upper insulating layer includes a first dielectric material, the second upper insulating layer includes a second dielectric material, and the first dielectric material has a different porosity than the second dielectric material. In some embodiments of the device, the first upper insulating layer includes a first dielectric material, the second upper insulating layer includes a second dielectric material, and the first dielectric material is under a different stress than the second dielectric material. In some embodiments of the device, the second upper insulating layer is wider than the first upper insulating layer. In some embodiments, the device further includes: an inter-layer dielectric on the first source/drain regions, the first insulating fin, the second source/drain regions, and the second insulating fin, where the first insulating fin and a first portion of the inter-layer dielectric collectively separate the first source/drain regions from each other, and where the second insulating fin and a second portion of the inter-layer dielectric collectively separate the second source/drain regions from each other.

In an embodiment, a device includes: a first insulating fin including a first lower insulating layer and a first upper insulating layer, the first upper insulating layer including a first dielectric material; a first gate structure extending along a sidewall of the first lower insulating layer and along a top surface of the first upper insulating layer; a second insulating fin including a second lower insulating layer and a second upper insulating layer, the second upper insulating layer including a second dielectric material, the second dielectric material different from the first dielectric material; and a second gate structure extending along a sidewall of the second lower insulating layer and along a top surface of the second upper insulating layer. In some embodiments of the device, the second dielectric material is composed of more nitrogen or oxygen than the first dielectric material. In some embodiments of the device, the second dielectric material is denser than the first dielectric material. In some embodiments of the device, the second dielectric material is more porous than the first dielectric material. In some embodiments of the device, the first dielectric material is under a tensile strain and the second dielectric material is under a compressive strain. In some embodiments of the device, the first gate structure is on a first channel region, the second gate structure is on a second channel region, and the first channel region is longer than the second channel region.

In an embodiment, a method includes: patterning a multi-layer stack to form a first trench between first nanostructures and to form a second trench between second nanostructures, the first trench wider than the second trench; depositing a first dielectric layer in the first trench and the second trench, the first dielectric layer including a first dielectric material; converting a first portion of the first dielectric layer at a first bottom of the first trench to a second dielectric material, a second portion of the first dielectric layer at a second bottom of the second trench remaining as the first dielectric material; and removing portions of the first dielectric layer above the first nanostructures and the second nanostructures to form a first insulating fin in the first trench and to form a second insulating fin in the second trench. In some embodiments, the method further includes: etching a first recess in the first insulating fin with a first etching process, the first etching process selectively etching the second dielectric material at a faster rate than the first dielectric material; and etching a second recess in the second insulating fin with a second etching process, the second etching process selectively etching the first dielectric material at a faster rate than the second dielectric material. In some embodiments of the method, the first insulating fin is exposed to the second etching process and the second insulating fin is exposed to the first etching process. In some embodiments of the method, converting the first portion of the first dielectric layer to the second dielectric material includes: modifying a composition of the first portion of the first dielectric layer. In some embodiments of the method, converting the first portion of the first dielectric layer to the second dielectric material includes: modifying a density of the first portion of the first dielectric layer. In some embodiments of the method, converting the first portion of the first dielectric layer to the second dielectric material includes: modifying a porosity of the first portion of the first dielectric layer. In some embodiments of the method, converting the first portion of the first dielectric layer to the second dielectric material includes: modifying a stress of the first portion of the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A device comprising:
first source/drain regions;
a first insulating fin between the first source/drain regions, the first insulating fin comprising a first lower insulating layer and a first upper insulating layer;
second source/drain regions; and
a second insulating fin between the second source/drain regions, the second insulating fin comprising a second lower insulating layer and a second upper insulating layer, the first lower insulating layer and the second lower insulating layer comprising the same dielectric material, the first upper insulating layer and the second upper insulating layer comprising different dielectric materials.

2. The device of claim 1, wherein the first upper insulating layer comprises a first dielectric material, the second upper insulating layer comprises a second dielectric material, and the first dielectric material has a different composition than the second dielectric material.

3. The device of claim 1, wherein the first upper insulating layer comprises a first dielectric material, the second upper insulating layer comprises a second dielectric material, and the first dielectric material has a different density than the second dielectric material.

4. The device of claim 1, wherein the first upper insulating layer comprises a first dielectric material, the second upper insulating layer comprises a second dielectric material, and the first dielectric material has a different porosity than the second dielectric material.

5. The device of claim 1, wherein the first upper insulating layer comprises a first dielectric material, the second upper insulating layer comprises a second dielectric material, and the first dielectric material is under a different stress than the second dielectric material.

6. The device of claim 1, wherein the second upper insulating layer is wider than the first upper insulating layer.

7. The device of claim 1, further comprising:
an inter-layer dielectric on the first source/drain regions, the first insulating fin, the second source/drain regions, and the second insulating fin, wherein the first insulating fin and a first portion of the inter-layer dielectric collectively separate the first source/drain regions from each other, and wherein the second insulating fin and a second portion of the inter-layer dielectric collectively separate the second source/drain regions from each other.

8. A device comprising:
a first insulating fin comprising a first lower insulating layer and a first upper insulating layer, the first upper insulating layer comprising a first dielectric material;
a first gate structure extending along a sidewall of the first lower insulating layer and along a top surface of the first upper insulating layer;
a second insulating fin comprising a second lower insulating layer and a second upper insulating layer, the second upper insulating layer comprising a second dielectric material, the second dielectric material different from the first dielectric material; and
a second gate structure extending along a sidewall of the second lower insulating layer and along a top surface of the second upper insulating layer.

9. The device of claim 8, wherein the second dielectric material is composed of more nitrogen or oxygen than the first dielectric material.

10. The device of claim 8, wherein the second dielectric material is denser than the first dielectric material.

11. The device of claim 8, wherein the second dielectric material is more porous than the first dielectric material.

12. The device of claim 8, wherein the first dielectric material is under a tensile strain and the second dielectric material is under a compressive strain.

13. The device of claim 8, wherein the first gate structure is on a first channel region, the second gate structure is on a second channel region, and the first channel region is longer than the second channel region.

14. A device comprising:
first channel regions, each of the first channel regions having a first length;
a first insulating fin between the first channel regions, the first insulating fin having a first width in a direction extending between the first channel regions, the first insulating fin comprising a first lower insulating layer and a first upper insulating layer;
second channel regions, each of the second channel regions having a second length, the second length being greater than the first length; and
a second insulating fin between the second channel regions, the second insulating fin having a second width in a direction extending between the second channel regions, the second width being greater than the first width, the second insulating fin comprising a second lower insulating layer and a second upper insulating layer, the first lower insulating layer and the second lower insulating layer comprising the same dielectric material, the first upper insulating layer and the second upper insulating layer comprising different dielectric materials.

15. The device of claim 14, wherein the first upper insulating layer comprises a first dielectric material, the second upper insulating layer comprises a second dielectric material, and the second dielectric material is composed of more nitrogen or oxygen than the first dielectric material.

16. The device of claim 14, wherein the first upper insulating layer comprises a first dielectric material, the second upper insulating layer comprises a second dielectric material, and the second dielectric material is denser than the first dielectric material.

17. The device of claim 14, wherein the first upper insulating layer comprises a first dielectric material, the second upper insulating layer comprises a second dielectric material, and the second dielectric material is more porous than the first dielectric material.

18. The device of claim 14, wherein the first upper insulating layer comprises a first dielectric material, the second upper insulating layer comprises a second dielectric material, the first dielectric material is under a tensile strain, and the second dielectric material is under a compressive strain.

19. The device of claim 14, further comprising:
first source/drain regions adjacent to the first channel regions, the first insulating fin separating the first source/drain regions from each other, a top surface of the first insulating fin being disposed beneath top surfaces of the first source/drain regions; and
second source/drain regions adjacent to the second channel regions, the second insulating fin separating the second source/drain regions from each other, a top surface of the second insulating fin being disposed beneath top surfaces of the second source/drain regions.

20. The device of claim 14, further comprising:
a first gate structure extending along the first channel regions, along a sidewall of the first lower insulating layer, and along a sidewall of the first upper insulating layer; and
a second gate structure extending along the second channel regions, along a sidewall of the second lower insulating layer, and along a sidewall of the second upper insulating layer.
